(19) United States
(12) Patent Application Publication
(10) Pub. No.: US 2026/0101636 A1
(43) Pub. Date: Apr. 9, 2026

(54) DISPLAY DEVICE AND ELECTRONIC DEVICE, AND METHOD OF MANUFACTURING DISPLAY DEVICE

(71) Applicant: Samsung Display Co., LTD., Yongin-si (KR)

(72) Inventors: Jong Woo JIN, Yongin-si (KR); Ki Hwan KIM, Yongin-si (KR); Myeong Ho KIM, Yongin-si (KR); Tetsuhiro TANAKA, Yongin-si (KR); Kyung Tae KIM, Yongin-si (KR); Ki Lim HAN, Yongin-si (KR)

(73) Assignee: Samsung Display Co., LTD., Yongin-si (KR)

(21) Appl. No.: 19/238,701

(22) Filed: Jun. 16, 2025

(30) Foreign Application Priority Data
Oct. 7, 2024 (KR) 10-2024-0135396

(51) Int. Cl. H10K 59/121; G09G 3/3233; H10K 59/12

(52) U.S. Cl. CPC H10K 59/1213; H10K 59/1201; G09G 3/3233; G09G 2300/0819; G09G 2300/0847; G09G 2300/0861; G09G 2320/0252; G09G 2320/045

(57) ABSTRACT

A display device includes a substrate including a display area and a non-display area, a first insulating layer disposed on the substrate and including oxygen, a first transistor including a first active layer disposed on a first portion of the first insulating layer and a first gate electrode overlapping the first active layer, and a second transistor including a second active layer disposed on a second portion of the first insulating layer and a second gate electrode overlapping the second active layer, wherein an oxygen concentration of the second portion of the first insulating layer is higher than an oxygen concentration of the first portion of the first insulating layer.

### CROSS-REFERENCE TO RELATED APPLICATION(S)

This application claims to and benefits from Korean Patent Application No. 10-2024-0135396 priority under 35 U.S.C. § 119, filed on Oct. 7, 2024 in the Korean Intellectual Property Office, the entire contents of which are incorporated herein by reference.

### BACKGROUND

### 1. Technical Field Embodiments of the disclosure relate to a display device, an electronic device, and a method of manufacturing display device.

### 2. Description of the Related Art

As the information society develops, demands for display devices for displaying images are increasing in various forms. Accordingly, various types of display devices, including light emitting display devices, are being developed. A display device may include multiple transistors.

### SUMMARY

Aspects of the disclosure provide a display device and an electronic device capable of improving the operating characteristics of transistors, and a method of manufacturing the display device.

However, aspects of the disclosure are not restricted to the one set forth herein. The above and other aspects of the disclosure will become more apparent to one of ordinary skill in the art to which the disclosure pertains by referencing the detailed description of the disclosure given below.

According to an embodiment, there is provided a display device including a substrate including a display area and a non-display area, a first insulating layer disposed on the substrate and including oxygen, a first transistor including a first active layer disposed on a first portion of the first insulating layer and a first gate electrode overlapping the first active layer, and a second transistor including a second active layer disposed on a second portion of the first insulating layer and a second gate electrode overlapping the second active layer. The oxygen concentration of the second portion of the first insulating layer may be higher than the oxygen concentration of the first portion of the first insulating layer.

In an embodiment, the first active layer and the second active layer may include an oxide semiconductor.

In an embodiment, the first active layer and the second active layer may be disposed on a same layer and include a same material, the first portion of the first insulating layer may be disposed in at least a portion of the display area, and the second portion of the first insulating layer may be disposed in the non-display area.

In an embodiment, the display device may further include a pixel disposed in the display area and the first transistor may include a driving transistor of the pixel.

In an embodiment, the first portion of the first insulating layer may be disposed in a portion of a pixel area where the pixel is disposed, and the second portion of the first insulating layer may be disposed in another portion of the pixel area.

In an embodiment, the second transistor may include a switching transistor disposed in the another portion of the pixel area, and a channel length of the switching transistor may be shorter than a channel length of the driving transistor.

In an embodiment, the display device may further include a driver or a demultiplexer disposed in the non-display area, and the second transistor may include a circuit transistor included in the driver or the demultiplexer.

In an embodiment, the display device may further include a second insulating layer disposed between the substrate and the first insulating layer.

In an embodiment, the first insulating layer may include silicon oxide and the second insulating layer may include silicon nitride.

In an embodiment, the display device may further include a gate insulating layer disposed between the first active layer and the first gate electrode and between the second active layer and the second gate electrode.

In an embodiment, the gate insulating layer may be disposed only on a portion of each of the first active layer and the second active layer and a channel region of each of the first active layer and the second active layer, and the gate insulating layer may expose another portion of each of the first active layer and the second active layer.

In an embodiment, the display device may further include a panel circuit layer including the first insulating layer, the first transistor, and the second transistor, and a light emitting element layer disposed on the panel circuit layer and including a light emitting element.

According to an embodiment, there is provided a method of manufacturing a display device, the method including forming a first insulating layer on a substrate, injecting oxygen into a portion of the first insulating layer to differentiate an oxygen concentration of a first portion of the first insulating layer and an oxygen concentration of a second portion of the first insulating layer, and forming a first transistor and a second transistor on the first portion and the second portion of the first insulating layer, respectively.

In an embodiment, the injecting of the oxygen into the portion of the first insulating layer may include forming a mask pattern on the first portion of the first insulating layer and exposing the second portion of the first insulating layer, forming an oxide semiconductor layer on the first insulating layer and on the mask pattern, and removing the mask pattern and the oxide semiconductor layer.

In an embodiment, the injecting of the oxygen into the portion of the first insulating layer may include forming an oxide semiconductor layer on the first insulating layer, etching the oxide semiconductor layer to form an oxide semiconductor pattern on the second portion of the first insulating layer and expose the first portion of the first insulating layer, performing heat treatment by applying heat to the oxide semiconductor pattern, and removing the oxide semiconductor pattern.

In an embodiment, the forming of the first transistor and the second transistor may include forming an active layer of the first transistor and an active layer of the second transistor on the first portion and the second portion of the first insulating layer, respectively, and forming a gate insulating layer, a gate electrode of the first transistor, and a gate electrode of the second transistor on the active layer of the first transistor and the active layer of the second transistor.

In an embodiment, the active layer of the first transistor and the active layer of the second transistor may include an oxide semiconductor.

In an embodiment, the method may further include forming a second insulating layer on the substrate before the forming of the first insulating layer. The first insulating layer may include silicon oxide and the second insulating layer may include silicon nitride.

According to an embodiment, there is provided an electronic device including a display module including a display panel and a processor that transmits an image data signal to the display module. The display panel may include a substrate including a display area and a non-display area, a first insulating layer disposed on the substrate and including oxygen, a first transistor including a first active layer disposed on a first portion of the first insulating layer and a first gate electrode overlapping the first active layer, and a second transistor including a second active layer disposed on a second portion of the first insulating layer and a second gate electrode overlapping the second active layer. An oxygen concentration of the second portion of the first insulating layer may be higher than an oxygen concentration of the first portion of the first insulating layer.

In an embodiment, the first active layer and the second active layer may include an oxide semiconductor.

According to an embodiment, in an electronic device and a method of manufacturing the display device according to embodiments, oxygen concentrations of a first portion and a second portion of a first insulating layer may differ, and a first transistor and a second transistor can be formed on the first portion and the second portion of the first insulating layer, respectively. According to embodiments, the characteristics of the first transistor and the second transistor may differ or be optimized according to the operating characteristics required for each of the first transistor and the second transistor.

However, effects according to the embodiments of the disclosure are not limited to those above and various other effects are incorporated herein.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a display device according to an embodiment;

FIG. 2 is a schematic plan view of a display panel of FIG. 1;

FIG. 3 is a schematic diagram of an equivalent circuit of a pixel according to an embodiment;

FIG. 4 is a graph illustrating the change in threshold voltage with respect to the channel length of an oxide transistor;

FIG. 5 is a schematic cross-sectional view of a display panel according to an embodiment;

FIG. 6 is a schematic cross-sectional view of a display panel according to an embodiment;

FIG. 7 is a schematic cross-sectional view of a display panel according to an embodiment;

FIG. 8 is a schematic cross-sectional view of a display panel according to an embodiment;

FIG. 9 is a flowchart illustrating a method of manufacturing a display device according to an embodiment;

FIGS. 10 through 22 are schematic cross-sectional views illustrating a method of manufacturing a display device according to an embodiment; and

FIGS. 23 through 25 are schematic cross-sectional views illustrating a method of manufacturing a display device according to an embodiment.

FIG. 26 is a schematic block diagram of an electronic device according to an embodiment of the disclosure.

FIG. 27 is a schematic diagram of an electronic device according to various embodiments of the disclosure.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc., (hereinafter individually or collectively referred to as “elements”), of the various embodiments may be otherwise combined, separated, interchanged, and/or redisposed without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals and/or reference characters denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may be different directions that are not perpendicular to one another.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc., may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may otherwise be oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, parts, and/or modules. Those skilled in the art will appreciate that these blocks, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, parts, and/or modules being implemented by microprocessors or other similar hardware, they may be programmed and controlled using software (e.g., microcode) to perform various functions discussed herein and may optionally be driven by firmware and/or software. It is also contemplated that each block, part, and/or module may be implemented by dedicated hardware, or as a combination of dedicated hardware to perform some functions and a processor (e.g., one or more programmed microprocessors and associated circuitry) to perform other functions. Also, each block, part, and/or module of some embodiments may be physically separated into two or more interacting and discrete blocks, parts, and/or modules without departing from the scope of the disclosure. Further, the blocks, parts, and/or modules of some embodiments may be physically combined into more complex blocks, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly defined herein.

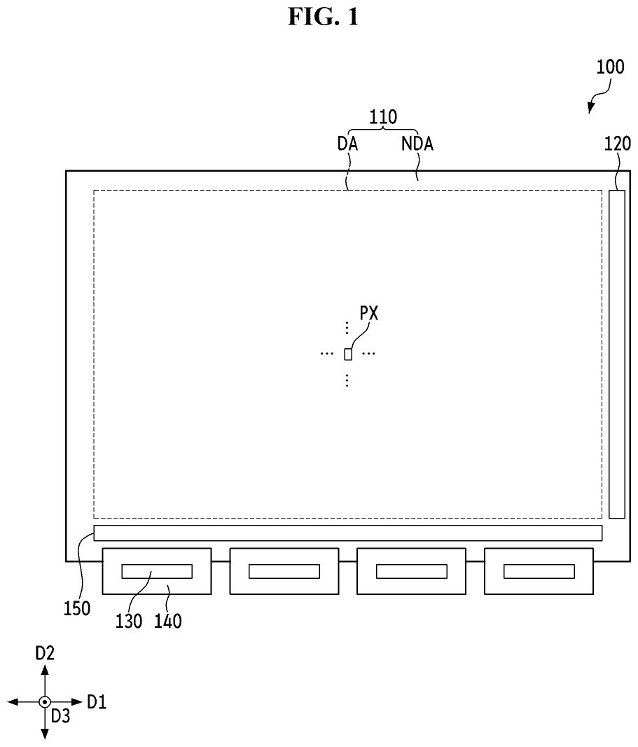

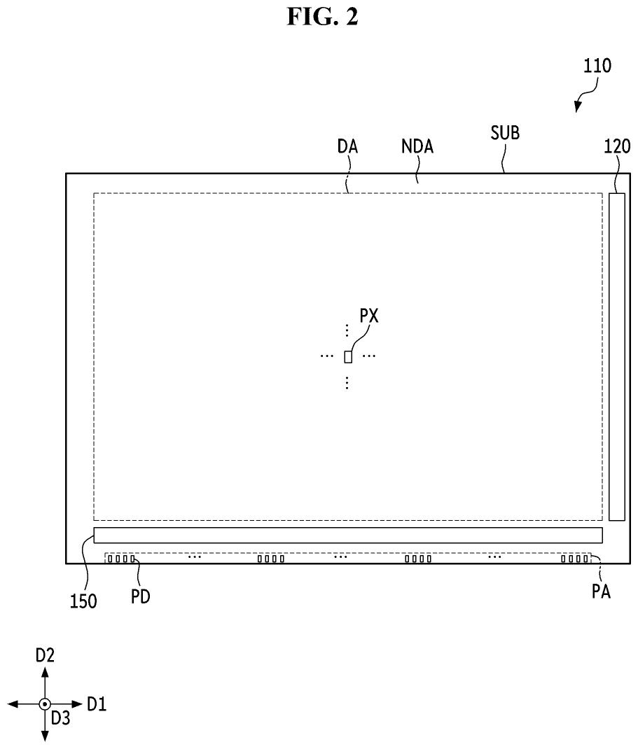

FIG. 1 is a schematic plan view of a display device 100 according to an embodiment. FIG. 2 is a schematic plan view of a display panel 110 of FIG. 1.

Referring to FIGS. 1 and 2, the display device 100 may be a device for displaying moving images or still images. The display device 100 may be included in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various electronic devices such as televisions, notebook computers, monitors, billboards and Internet of things (IoT) devices and may be used as a display screen of the above electronic devices. The display device 100 may also be included in other types of electronic devices in addition to the electronic devices above.

In an embodiment, the display device 100 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro-or nano-light emitting diode. However, embodiments are not limited thereto. For example, the display device 100 may also be a display device of a type other than a light emitting display device. Embodiments in which the display device 100 is a light emitting display device (e.g., an organic light emitting display device) will be disclosed below.

The display device 100 may include the display panel 110 which includes pixels PX and a first driver 120 and a second driver 130 which supply driving signals to the pixels PX. In an embodiment, the display device 100 may further include a demultiplexer 150 (e.g., a data distributor) electrically connected between the pixels PX and the second driver 130.

The display device 100 may further include additional elements. For example, the display device 100 may further include a power supply part for supplying driving voltages to the pixels PX, the first driver 120 and the second driver 130 and a timing controller for controlling the operation of the first driver 120, the second driver 130 and/or the demultiplexer 150.

The display panel 110 may include a display area DA and a non-display area NDA. The display area DA may be an area that displays an image by including the pixels PX. For example, the display area DA may include pixel areas where the pixels PX are disposed. The non-display area NDA may be an area other than the display area DA. An image may not be disposed in the non-display area NDA. The non-display area NDA may be located around the display area DA.

In FIGS. 1 and 2, a first direction D1, a second direction D2, and a third direction D3 are defined. In an embodiment, the first direction D1 may be a horizontal direction of the display panel 110, and the second direction D2 may be a vertical direction of the display panel 110. The third direction D3 may be a thickness direction of the display panel 110.

In an embodiment, the display panel 110 may be rectangular in plan view. In FIGS. 1 and 2, a rectangular display panel 110 whose horizontal length is longer than its vertical length is illustrated. However, the shape of the display panel 110 is not limited thereto. For example, the display panel 110 may also have a shape whose vertical length is longer than its horizontal length or may have a square shape. The display panel 110 may include angled corners or rounded corners.

The planar shape of the display panel 110 is not limited to the quadrilateral shapes above. For example, the display panel 110 may also have a polygonal shape other than a quadrilateral shape, a circular shape, an oval shape, an irregular shape, or other shapes in plan view.

The display panel 110 may be provided as a rigid panel that is substantially not deformed or may be provided as a flexible panel that may be deformed, for example, may be folded, bent, or rolled in at least a portion. The display panel 110 may be provided to the display device 100 in an unbent state or may be provided to the display device 100 in a bent state in some sections.

The display panel 110 may include a substrate SUB and the pixels PX disposed on the substrate SUB. The pixels PX may be disposed on the display area DA of the substrate SUB.

The substrate SUB may be a base member for manufacturing or providing the display panel 110 and may form a base surface of the display panel 110. The substrate SUB may include the display area DA and the non-display area NDA around the display area DA.

The display area DA may have various shapes according to embodiments. For example, the display area DA may have a quadrilateral shape, a polygonal shape other than the quadrilateral shape, a circular shape, an oval shape, an irregular shape, or other shapes. In an embodiment, the display area DA may have a shape that matches the shape of the display panel 110.

The pixels PX may be disposed in the display area DA. For example, the display area DA may include pixel areas where the pixels PX are disposed, respectively.

In an embodiment, the display device 100 may be a light emitting display device, and each of the pixels PX may include a light emitting element located in an emission area and a pixel circuit connected (e.g., electrically connected) to the light emitting element. In the description of embodiments, the term “connection” may include the meaning of electrical connection and/or physical connection. Each pixel circuit may include multiple transistors (e.g., a driving transistor that generates a driving current corresponding to a data signal and at least one switching transistor) and a capacitor (e.g., a storage capacitor).

The non-display area NDA may include a pad area PA where pads PD are disposed. In an embodiment, the non-display area NDA may further include a circuit area located on at least one side of the display area DA. At least one driver, the pads PD, and/or lines may be disposed in the non-display area NDA.

At least one driver for driving the pixels PX or a part of the driver may be disposed in the circuit area of the non-display area NDA. For example, circuit elements constituting the first driver 120, e.g., transistors and capacitors constituting stage circuits of the first driver 120 may be disposed on the circuit area (e.g., a first circuit area disposed on a left and/or right side of the display area DA) of the substrate SUB.

In an embodiment, the circuit elements of the first driver 120 may be formed in the display panel 110 together with the pixels PX. In an embodiment, the transistors of the first driver 120 may be transistors of substantially the same or similar type and/or structure as pixel transistors included in the pixels PX and may be formed at the same time as the pixel transistors. For example, each of the transistors of the first driver 120 may have substantially the same or similar structure as a driving transistor or a switching transistor of each pixel PX.

In an embodiment, the demultiplexer 150 may be further disposed in the circuit area of the non-display area NDA. For example, the demultiplexer 150 may be disposed on the circuit area (e.g., a second circuit area disposed between the display area DA and the pad area PA) of the substrate SUB.

The pads PD may be disposed in the pad area PA. At least one circuit board 140 may be disposed or bonded on the pad area PA. In an embodiment, multiple circuit boards 140 connected to different pads PD may be disposed on the pad area PA of the display panel 110. The pads PD may include signal pads and power pads for transmitting driving signals and driving voltages needed to drive the pixels PX, the first driver 120, and/or the demultiplexer 150 into the display panel 110.

The first driver 120 and the second driver 130 may generate driving signals for controlling the operation timing and luminance of the pixels PX and supply the driving signals to the pixels PX. For example, the first driver 120 may be a gate driver including a scan driver and may be connected to the pixels PX through gate lines. The first driver 120 may supply gate signals (e.g., gate signals (including scan signals) for controlling the operation timing of the pixels PX) to the pixels PX. The second driver 130 may be a data driver including source driving circuits and may be connected to the pixels PX through data lines. The second driver 130 may supply data signals to the pixels PX.

In an embodiment, at least one of the first driver 120 and the second driver 130 or a part of the at least one driver may be built into the display panel 110. For example, the first driver 120 or a part of the first driver 120 may be disposed on the substrate SUB of the display panel 110 and may be disposed and/or formed in the non-display area NDA.

In FIG. 1, the first driver 120 may be formed on a side of the display area DA (e.g., in the first circuit area located in the non-display area NDA on the right side of the display area DA). However, embodiments are not limited thereto. For example, the first driver 120 may also be located only on another side of the display area DA (e.g., in the non-display area NDA on the left side of the display area DA) or may be located on both sides of the display area DA (e.g., in the non-display area NDA on the left and right sides of the display area DA). For example, a part of the first driver 120 may be located in the non-display area NDA, and the other part of the first driver 120 may be located in a non-emission area (e.g., an area between the emission areas of the pixels PX) in the display area DA.

In an embodiment, the other of the first driver 120 and the second driver 130 or a part of the other driver may be disposed or formed outside the display panel 110 and electrically connected to the display panel 110. For example, the second driver 130 may be implemented as multiple integrated circuit chips and disposed on the circuit boards 140 electrically connected to the pixels PX of the display panel 110. However, embodiments are not limited thereto. For example, the second driver 130 may also be implemented as at least one integrated circuit chip and mounted on the non-display area NDA of the display panel 110.

The circuit boards 140 may be electrically connected to the display panel 110 through the pads PD. In an embodiment, each of the circuit boards 140 may be, but is not limited to, a flexible printed circuit board (FPCB), a printed circuit board (PCB), or a flexible film such as a chip on film (COF). In an embodiment, each of the circuit boards 140 may be electrically connected to the timing controller and/or the power supply part through another circuit board or a connector.

The demultiplexer 150 may transmit data signals output from the second driver 130 to the data lines, respectively. For example, the demultiplexer 150 may function as a data distributor that distributes data signals, which are output from channels of the second driver 130 and input to input terminals of the demultiplexer 150 through data pads, to multiple data lines. The demultiplexer 150 may include transistors connected between the data pads (or output terminals of the second driver 130), which are electrically connected to the second driver 130, and the data lines and operating as switching elements.

In an embodiment, the transistors of the demultiplexer 150 may be transistors of substantially the same or similar type and/or structure as the pixel transistors included in the pixels PX and may be formed at the same time as the pixel transistors. For example, each of the transistors of the demultiplexer 150 may have substantially the same or similar structure as a driving transistor or a switching transistor of each pixel PX.

In the description of embodiments, transistors included in a circuit part for driving the pixels PX and disposed or formed in the display panel 110 together with the pixel transistors, like the transistors of the first driver 120 and the transistors of the demultiplexer 150, may be referred to as “circuit transistors.” In case that the transistors of the first driver 120 and the transistors of the demultiplexer 150 are to be distinguished from each other, the transistors of the first driver 120 may be referred to as “first circuit transistors,” and the transistors of the demultiplexer 150 may be referred to as “second circuit transistors.”

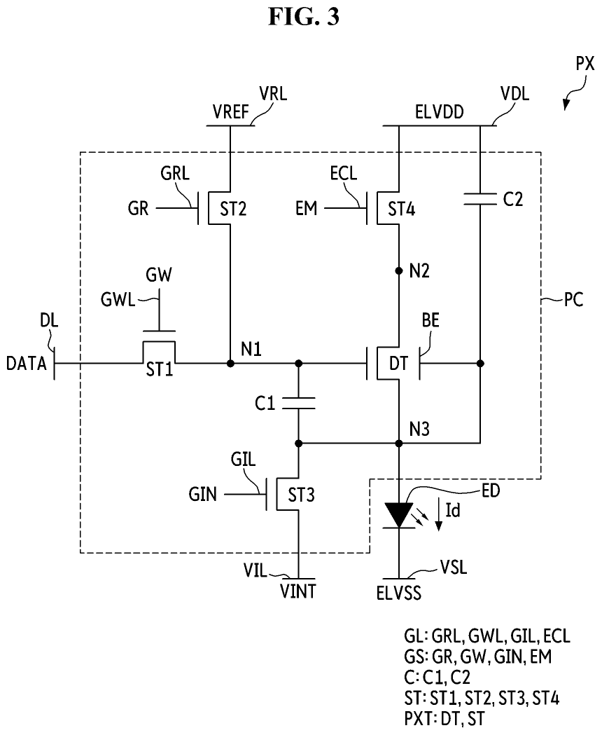

FIG. 3 is a schematic diagram of an equivalent circuit of a pixel PX according to an embodiment. For example, FIG. 3 illustrates a pixel PX of a light emitting display device including a light emitting element ED. The type and/or structure of the pixel PX that can be included in the display device 100 may vary according to embodiments.

Referring to FIG. 3, the pixel PX may include a light emitting element ED and a pixel circuit PC electrically connected to the light emitting element ED. The light emitting element ED may be a light source of the pixel PX and may be, but is not limited to, an organic light emitting diode. The pixel circuit PC may control the light emitting timing and luminance of the light emitting element ED.

The pixel circuit PC may supply a driving current Id to the light emitting element ED in response to driving signals supplied from the first driver 120 and the second driver 130. For example, the pixel circuit PC may supply the driving current Id to the light emitting element ED in response to gate signals GS supplied from the first driver 120 through gate lines GL, respectively, and a data signal DATA supplied from the second driver 130 (or the demultiplexer 150) through a data line DL.

The pixel PX may be connected to a first gate line GWL that transmits a first gate signal GW (e.g., a scan signal), a second gate line GIL that transmits a second gate signal GIN, a third gate line GRL that transmits a third gate signal GR, an emission control line ECL that transmits an emission control signal EM, and the data line DL that transmits the data signal DATA. The pixel PX may be connected to a first power line VDL that transmits a first driving voltage ELVDD (e.g., a high-potential first pixel voltage or anode voltage) and a second power line VSL that transmits a second driving voltage ELVSS (e.g., a low-potential second pixel voltage or cathode voltage). In an embodiment, the pixel PX may be further connected to an initialization power line VIL that transmits an initialization voltage VINT and a reference power line VRL that transmits a reference voltage VREF.

The pixel circuit PC may include pixel transistors PXT and at least one capacitor C. The pixel transistors PXT may include a driving transistor DT and at least one switching transistor ST of the pixel PX.

In an embodiment, the pixel circuit PC may include multiple switching transistors ST. For example, the pixel circuit PC may include a first switching transistor ST1, a second switching transistor ST2, a third switching transistor ST3, and a fourth switching transistor ST4. In an embodiment, the pixel circuit PC may include multiple capacitors C. For example, the pixel circuit PC may include a first capacitor C1 and a second capacitor C2.

The driving transistor DT may control the magnitude of the driving current Id supplied to the light emitting element ED according to a gate-source voltage. The switching transistors ST may be turned on or off according to their respective gate-source voltages. Depending on the type (e.g., a P-type or N-type transistor) and/or operating conditions of each of the pixel transistors PXT, a first electrode of each of the pixel transistors PXT may be a drain electrode (or a drain region) or a source electrode (or a source region), and a second electrode may be an electrode different from the first electrode. For example, in case that the first electrode is a drain electrode, the second electrode may be a source electrode.

Although FIG. 3 illustrates an embodiment in which all of the pixel transistors PXT are N-type transistors, the type of the pixel transistors PXT is not limited thereto. For example, at least one pixel transistor PXT may be formed as a P-type transistor.

In an embodiment, the pixel transistors PXT may be located in each pixel area and may be oxide transistors including an oxide semiconductor (also referred to as “oxide semiconductor transistors”). For example, an active layer of each of the pixel transistors PXT may include an oxide semiconductor. However, embodiments are not limited thereto. For example, at least one pixel transistor PXT may be made of a semiconductor material (e.g., amorphous silicon or polysilicon) other than an oxide semiconductor.

In an embodiment, the pixel transistors PXT disposed in the display panel 110 as well as the pixel transistors PXT included in each pixel PX may all be oxide transistors including an oxide semiconductor. Oxide semiconductors have high carrier mobility and low leakage current. Therefore, in case that the driving time of the oxide transistors is long, a large voltage drop may not occur. For example, in the case of a pixel PX including oxide transistors, even in case that the pixel PX is driven at a low frequency, a change in the luminance and/or color of an image due to a voltage drop may not be large. Therefore, the pixel PX can be driven at a low frequency. In case that the pixel transistors PXT are formed as oxide transistors, the leakage current of the pixel PX can be reduced or prevented, and power consumption can be reduced.

Since oxide semiconductors are sensitive to light, the amount of current may be changed by external light. In an embodiment, a light blocking pattern or a light blocking electrode (e.g., a bottom electrode BE or a back-gate electrode) may be disposed under an active layer included in at least one pixel transistor PXT to block external light. Accordingly, the operating characteristics of the pixel transistor PXT can be stabilized.

The driving transistor DT may include a gate electrode connected to a first node N1, a first electrode (e.g., a drain electrode) connected to a second node N2, and a second electrode (e.g., a source electrode) connected to a third node N3. The first electrode of the driving transistor DT may be connected to the first power line VDL via the fourth switching transistor ST4, and the second electrode may be connected to the light emitting element ED. The driving transistor DT may control the driving current Id flowing to the light emitting element ED in response to the data signal DATA transmitted to the first node N1.

In an embodiment, the driving transistor DT may further include the bottom electrode BE (or a light blocking layer) connected to the third node N3. In case that the driving transistor DT is formed as a double-gate transistor (e.g., a double-gate transistor of a source-sync structure) by connecting the bottom electrode BE of the driving transistor DT to the third node N3, the operating characteristics of the driving transistor DT can be improved. The bottom electrode BE of the driving transistor DT may be disposed under an active layer of the driving transistor DT to block external light.

The first switching transistor ST1 may include a gate electrode connected to the first gate line GWL, a first electrode connected to the data line DL, and a second electrode connected to the first node N1. The first switching transistor ST1 may be turned on by the first gate signal GW (e.g., the first gate signal GW of a gate-on voltage) transmitted to the first gate line GWL and may connect the data line DL and the first node N1. Accordingly, the data signal DATA transmitted to the data line DL may be transmitted to the first node N1.

The second switching transistor ST2 may include a gate electrode connected to the third gate line GRL, a first electrode connected to the reference power line VRL, and a second electrode connected to the first node N1. The second switching transistor ST2 may be turned on by the third gate signal GR transmitted to the third gate line GRL and may transmit the reference voltage VREF transmitted to the reference power line VRL to the first node N1.

The third switching transistor ST3 may include a gate electrode connected to the second gate line GIL, a first electrode connected to the third node N3, and a second electrode connected to the initialization power line VIL. The third switching transistor ST3 may be turned on by the second gate signal GIN transmitted to the second gate line GIL and may transmit the initialization voltage VINT transmitted to the initialization power line VIL to the third node N3.

The fourth switching transistor ST4 may include a gate electrode connected to the emission control line ECL, a first electrode connected to the first power line VDL, and a second electrode connected to the second node N2 (or the first electrode of the driving transistor DT). The fourth switching transistor ST4 may be turned on by the emission control signal EM transmitted to the emission control line ECL (e.g., the emission control signal EM of a gate-on voltage) and may control the emission timing of the pixel PX.

Each of the switching transistors ST may or may not include a bottom electrode (or a light blocking layer) under an active layer. In an embodiment, at least one of the switching transistors ST may include a bottom electrode, and the bottom electrode of the at least one switching transistor ST may be connected to the gate electrode of the switching transistor ST. In case that the bottom electrode of the switching transistor ST is connected to the gate electrode, the off-characteristics and switching speed of the switching transistor ST can be improved, an additional voltage tolerance range can be secured, leakage current can be reduced, and voltage stability can be improved. In an embodiment, the bottom electrode may not be provided under the active layer of each of the switching transistors ST.

The first capacitor C1 may be connected between the first node N1 and the third node N3. The first capacitor C1 may be a storage capacitor of the pixel PX and may store a voltage corresponding to the data signal DATA (e.g., a data voltage).

The second capacitor C2 may be connected between the first power line VDL and the third node N3. In an embodiment, the capacity of the second capacitor C2 may be smaller than the capacity of the first capacitor C1.

The light emitting element ED may be connected between the third node N3 and the second power line VSL. For example, the light emitting element ED may include a first electrode (e.g., an anode) connected to the third node N3, a second electrode (e.g., a cathode) facing the first electrode and connected to the second power line VSL, and a light emitting layer disposed between the first electrode and the second electrode. In an embodiment, the first electrode of the light emitting element ED may be an individual electrode individually provided in each pixel PX, and the second electrode of the light emitting element ED may be a common electrode shared by multiple pixels PX. The light emitting element ED may emit light with a luminance corresponding to the driving current Id during a period in which the driving current Id is supplied from the pixel circuit PC.

In an embodiment, the driving transistor DT and the switching transistors ST of the pixel PX may have different channel lengths. For example, the driving transistor DT and the switching transistors ST of the pixel PX may have channel lengths that are differentiated or optimized to secure or improve the characteristics required of the pixel transistors PXT.

For example, the driving transistor DT may be formed as a long-channel transistor having a long channel length (e.g., a long channel length compared with a channel length of at least one switching transistor ST) and a long on-off transition time. Accordingly, a driving voltage range of the driving transistor DT can be expanded or secured, and the driving current Id can be precisely controlled in response to the data signal DATA.

On the other hand, the switching transistors ST (or at least one of the switching transistors ST) may be formed as short-channel transistors capable of performing a high-speed switching operation due to their short on-off transition time. Accordingly, the response speed of the pixel PX can be improved or secured.

In FIG. 3, the switching transistors ST of the pixel PX are illustrated as an example of short-channel transistors. However, short-channel transistors that can be included in the display panel 110 are not limited to the switching transistors ST of the pixel PX. For example, some or all of the circuit transistors included in the first driver 120 and/or the demultiplexer 150 of FIGS. 1 and 2 may also be formed as short-channel transistors.

For example, switching transistors of the first driver 120, including buffer transistors included in the stage circuits of the first driver 120 (e.g., a pull-up transistor and a pull-down transistor of each stage circuit), and transistors forming switching elements of the demultiplexer 150 may be formed as short-channel transistors. In case that the circuit transistors of the first driver 120 and/or the demultiplexer 150 are formed as short-channel transistors, the operating speed of the first driver 120 and/or the demultiplexer 150 can be improved, and the non-display area NDA (e.g., the circuit area of the non-display area NDA) can be reduced.

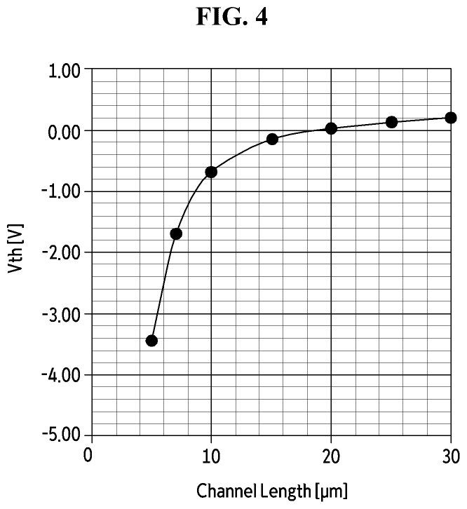

FIG. 4 is a graph illustrating the change in threshold voltage Vth with respect to the channel length of an oxide transistor. For example, FIG. 4 illustrates the change in threshold voltage Vth with respect to the channel length of an oxide transistor including an active layer made of indium-gallium-zinc oxide (IGZO).

Referring to FIG. 4, as the channel length of the oxide transistor (e.g., the length of a region where the active layer made of an oxide semiconductor and a gate electrode overlap) decreases, the threshold voltage Vth of the oxide transistor may decrease. For example, a negative shift in which threshold voltage Vth shifts in a negative direction as channel length decreases may occur in the oxide transistor.

The negative shift may change the electrical characteristics of the oxide transistor, causing problems such as current flowing in the oxide transistor in an unintended state or leakage current occurring or increasing in the oxide transistor in a turned-off state. For example, in at least one short-channel transistor (e.g., a short-channel oxide transistor) that includes an oxide semiconductor and has a short channel length, such as a switching transistor ST of a pixel PX or a circuit transistor, roll-off may occur due to a short-channel effect. Accordingly, problems such as a decrease in the performance of the short-channel transistor or an increase in leakage current may occur.

To prevent or improve the above problems, the channel length of the short-channel transistor may be increased. The size (e.g., area) of the short-channel transistor may however increase, resulting in space constraints or a decrease in the response speed of the short-channel transistor.

The negative shift of the threshold voltage of the short-channel transistor may also be prevented or minimized by changing process conditions without increasing the channel length of the short-channel transistor. However, in case that the short-channel transistor and a driving transistor DT of the pixel PX are formed simultaneously using the same oxide semiconductor, a threshold voltage of the driving transistor DT of the pixel PX may change due to the process conditions changed to cause the threshold voltage of the short-channel transistor to change in a positive direction (e.g., to cause a positive shift of the threshold voltage). For example, the threshold voltage of the driving transistor DT may increase. Accordingly, the reliability of the driving transistor DT may decrease. For example, as the threshold voltage of the driving transistor DT increases, the deterioration of the driving transistor DT may become more severe, which may cause a change in the characteristics or a decrease in the performance of the driving transistor DT.

Accordingly, embodiments to be described below disclose a display device and a method of manufacturing the same which can simultaneously improve or secure the operating characteristics of some transistors of the display panel 110, including the driving transistor DT of each pixel PX disposed in the display area DA, and the operating characteristics of other transistors of the display panel 110 including short-channel transistors (e.g., at least one switching transistor ST included in each pixel PX and/or at least one circuit transistor) disposed in the display area DA and/or the non-display area NDA. For example, the embodiments disclose a display device and a method of manufacturing the same which can prevent or minimize a change in the characteristics or a deterioration in the performance of some transistors including the driving transistor DT of each pixel PX and prevent or minimize a negative shift of a threshold voltage of short-channel transistors located in a specific area (e.g., a selected area) without increasing a channel length of the short-channel transistors.

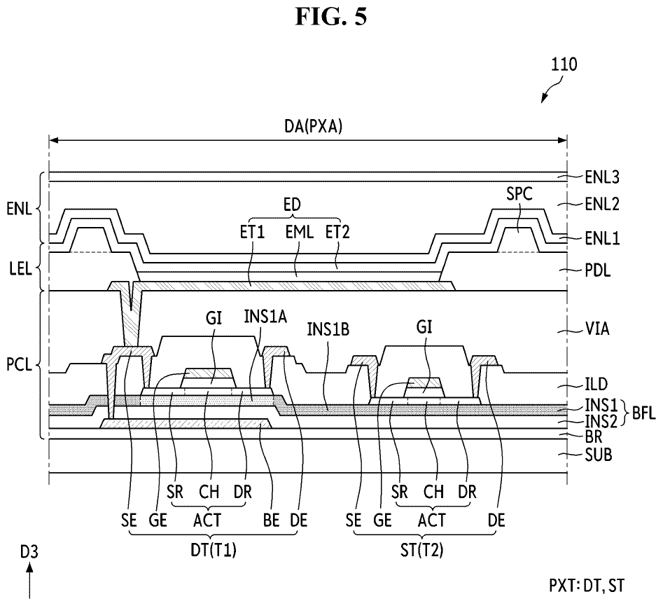

FIG. 5 is a schematic cross-sectional view of a display panel 110 according to an embodiment. For example, FIG. 5 illustrates a portion of the display area DA of the display panel 110. FIG. 5 shows a light emitting display panel including a light emitting element ED (e.g., an organic light emitting diode) as an example of the display panel 110 to which embodiments are applied.

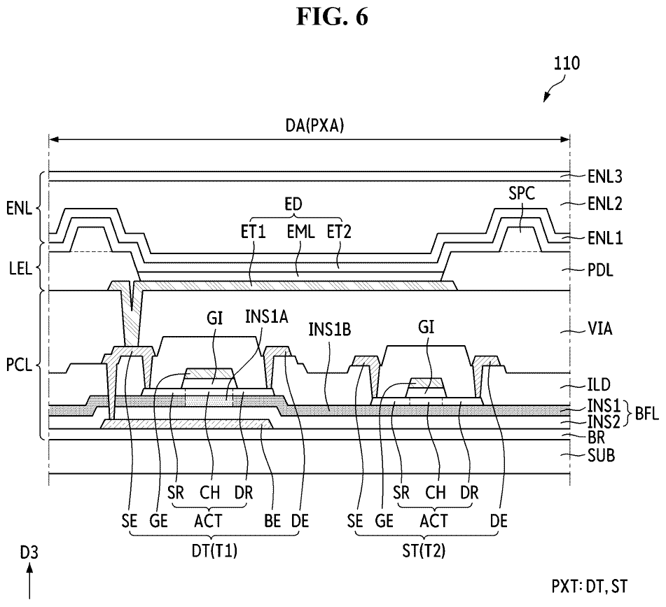

FIG. 6 is a schematic cross-sectional view of a display panel 110 according to an embodiment. FIGS. 5 and 6 show different embodiments in relation to a first insulating layer INS1 disposed under active layers ACT of pixel transistors PXT.

Referring to FIGS. 5 and 6, the display panel 110 may include a substrate SUB (or a base layer), a panel circuit layer PCL, a light emitting element layer LEL, and an encapsulation layer ENL. The panel circuit layer PCL, the light emitting element layer LEL, and the encapsulation layer ENL may be disposed on the substrate SUB to overlap each other. For example, in the display area DA, the panel circuit layer PCL, the light emitting element layer LEL, and the encapsulation layer ENL may be sequentially disposed on the substrate SUB in the third direction D3.

In an embodiment, the display panel 110 may further include additional elements disposed on and/or under the encapsulation layer ENL. For example, the display panel 110 may further include at least one of a sensor layer (e.g., a touch sensor layer), an optical layer (e.g., a color filter layer and/or a wavelength conversion layer), and a protective layer (e.g., a protective film, an insulating layer, an upper substrate, and/or a window). Each of the sensor layer, the optical layer, and/or the protective layer may be disposed on the encapsulation layer ENL or may be disposed between the light emitting element layer LEL and the encapsulation layer ENL.

The substrate SUB may be a base member for forming the display panel 110 and may be rigid or flexible. In an embodiment, the substrate SUB may be a substrate that includes an insulating material such as glass and has rigid characteristics. The substrate SUB may not be bent. For example, the substrate SUB may be a flexible substrate that includes polyimide or other insulating materials and can be bent, folded, rolled, etc. The substrate SUB may or may not be bent.

The panel circuit layer PCL (e.g., a backplane circuit layer or a thin-film transistor layer) may be disposed on the substrate SUB. The panel circuit layer PCL may include circuit elements of pixels PX, including pixel transistors PXT and capacitors C, and lines (e.g., signal lines and power lines). In an embodiment, the panel circuit layer PCL may further include circuit elements of the first driver 120 and/or the demultiplexer 150 (e.g., circuit transistors and/or capacitors included in the first driver 120 and/or the demultiplexer 150) and/or additional conductive patterns (e.g., bridge patterns).

FIG. 5 illustrates, as an example of the circuit elements that can be disposed in the panel circuit layer PCL, one switching transistor ST and one driving transistor DT disposed in a pixel area PXA, in which a pixel PX is disposed, and included in a pixel circuit PC of the pixel PX. For example, the driving transistor DT of FIG. 5 may be the driving transistor DT of FIG. 3, and the switching transistor ST of FIG. 5 may be one of the first through fourth switching transistors ST1 through ST4 of FIG. 3.

In an embodiment, the pixel transistors PXT may be formed simultaneously using the same material and may have substantially the same or similar cross-sectional structure. For example, the driving transistor DT and the switching transistor ST of the pixel PX may be formed simultaneously using the same oxide semiconductor and may have substantially the same or similar cross-sectional structure. For example, active layers ACT of the driving transistor DT and the switching transistor ST of the pixel PX may be disposed on a same layer (e.g., on the first insulating layer INS1) in the panel circuit layer PCL and may include a same oxide semiconductor.

The panel circuit layer PCL may include multiple conductive layers and at least one semiconductor layer disposed on the substrate SUB (or a barrier layer BR). The panel circuit layer PCL may further include multiple insulating layers and/or insulating patterns disposed on the substrate SUB (or the barrier layer BR).

Patterns included in the conductive layers of the panel circuit layer PCL may include electrodes constituting circuit elements of the panel circuit layer PCL, conductive patterns and/or lines connected to the circuit elements, etc. The patterns included in each conductive layer of the panel circuit layer PCL (e.g., the electrodes, conductive patterns and/or lines of each conductive layer) may include at least one conductive material. For example, the patterns included in each conductive layer of the panel circuit layer PCL may include at least one of copper (Cu), titanium (Ti), molybdenum (Mo), aluminum (Al), chromium (Cr), gold (Au), silver (Ag), platinum (Pt), palladium (Pd), nickel (Ni), neodymium (Nd), iridium (Ir), tantalum (Ta), tungsten (W), magnesium (Mg), other metals, an alloy thereof, other conductive materials, or a combination thereof. In an embodiment, patterns included in the same conductive layer may be formed simultaneously using the same conductive material.

Patterns included in the semiconductor layer of the panel circuit layer PCL may include the active layers ACT of transistors (e.g., pixel transistors PXT and circuit transistors) disposed in the pixel circuit layer PCL. In an embodiment, the active layers ACT of the pixel transistors PXT and the circuit transistors may be formed simultaneously using the same semiconductor material (e.g., the same oxide semiconductor). Accordingly, the active layers ACT of the pixel transistors PXT and the circuit transistors may be disposed on a same layer and may include the same semiconductor material.

The insulating layers and/or insulating patterns of the panel circuit layer PCL may include the barrier layer BR, a buffer layer BFL, a gate insulating layer GI, an interlayer insulating layer ILD, and a planarization layer VIA sequentially disposed on the substrate SUB in the third direction D3. Each of the insulating layers and/or insulating patterns of the panel circuit layer PCL may include an inorganic insulating material or an organic insulating material and may be composed of a single layer or multiple layers.

In an embodiment, at least one of the insulating layers of the panel circuit layer PCL may be disposed over the entire display area DA. For example, the barrier layer BR, the buffer layer BFL, the interlayer insulating layer ILD, and the planarization layer VIA may be disposed over the entire display area DA.

The structure of the panel circuit layer PCL will be described layer by layer. First, the barrier layer BR may be disposed on the substrate SUB. The barrier layer BR may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating materials). The barrier layer BR may protect the pixels PX from moisture introduced through the substrate SUB which is vulnerable to moisture penetration. The barrier layer BR may also be omitted.

A first conductive layer (e.g., a lower conductive layer) including a bottom electrode BE (or a light blocking layer) of at least one transistor may be disposed on the barrier layer BR (or the substrate SUB). For example, the bottom electrode BE (or the light blocking layer) of the driving transistor DT may be disposed on the barrier layer BR. The bottom electrode BE may be disposed under the active layer ACT to overlap a channel region CH of the driving transistor DT. In an embodiment, the bottom electrode BE may also overlap at least a portion of each of a source region SR and a drain region DR of the driving transistor DT, but embodiments are not limited thereto. Each of the patterns of the first conductive layer including the bottom electrode BE may include at least one conductive material and may be composed of a single layer or multiple layers.

In an embodiment, the bottom electrode BE may be electrically connected to an electrode (e.g., a source electrode SE) of the driving transistor DT and may be utilized as an electrode for adjusting the characteristics of the driving transistor DT. For example, the bottom electrode BE may be electrically connected to the source electrode SE of the driving transistor DT. In case that the bottom electrode BE is electrically connected to the electrode of the driving transistor DT, it may be viewed as an element included in the driving transistor DT. The bottom electrode BE disposed under the active layer ACT of the driving transistor DT may block external light from being incident on the channel region CH of the driving transistor DT. In an embodiment, in case that the transistors of the panel circuit layer PCL do not include the bottom electrode BE or the light blocking layer, the first conductive layer may be omitted.

The buffer layer BFL may be disposed on the barrier layer BR and the bottom electrode BE. The buffer layer BFL may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating materials).

In an embodiment, the buffer layer BFL may be an insulating layer including two or more layers. For example, the buffer layer BFL may include a second insulating layer INS2 disposed on the barrier layer BR and the first insulating layer INS1 disposed on the second insulating layer INS2.

The first insulating layer INS1 and the second insulating layer INS2 may include different insulating materials. In an embodiment, each of the first insulating layer INS1 and the second insulating layer INS2 may include an inorganic insulating material, and the types and/or compositions of the inorganic insulating materials included in the first insulating layer INS1 and the second insulating layer INS2 may be different. Since the buffer layer BFL includes the first insulating layer INS1 and the second insulating layer INS2 made of different materials, the insulating characteristics of the buffer layer BFL can be improved or secured.

In an embodiment, the first insulating layer INS1 may include oxygen. For example, the first insulating layer INS1 may be a silicon oxide layer including silicon oxide (SiOₓ). However, embodiments are not limited thereto, and the first insulating layer INS1 may also include other insulating materials including oxygen.

In an embodiment, the first insulating layer INS1 may be formed to have a different oxygen concentration in each portion. For example, after the first insulating layer INS1 is formed, a process of additionally supplying or injecting oxygen to a portion of the first insulating layer INS1 may be performed. Accordingly, the first insulating layer INS1 may include a first portion INS1A having a low oxygen concentration and a second portion INS1B having a higher oxygen concentration than the first portion INS1A. In an embodiment, the second portion INS1B of the first insulating layer INS1 may correspond to an oxygen-excessive region. For example, in case that the oxygen concentration (or layer density according to the oxygen concentration) of the first insulating layer INS1 is measured using secondary ion mass spectrometry (SIMS) analysis or other analysis methods, the oxygen concentration measured in the second portion INS1B of the first insulating layer INS1 which includes a portion under or around the active layer ACT of a specific transistor may be higher than the oxygen concentration measured in the first portion INS1A of the first insulating layer INS1 which includes a portion under or around the active layer ACT of another transistor. Accordingly, a threshold voltage of the transistor disposed on the second portion INS1B of the first insulating layer INS1 can be adjusted or optimized.

In an embodiment, the first insulating layer INS1 may include the first portion INS1A and the second portion INS1B in each pixel area PXA. The first portion INS1A of the first insulating layer INS1 may be disposed under the active layer ACT of at least one pixel transistor PXT including the driving transistor DT. For example, as illustrated in FIGS. 5 and 6, the first portion INS1A of the first insulating layer INS1 may overlap at least a portion of the active layer ACT of the driving transistor DT. For example, the first portion INS1A of the first insulating layer INS1 may overlap the channel region CH included in the active layer ACT of the driving transistor DT.

In an embodiment, as illustrated in FIG. 5, the first portion INS1A of the first insulating layer INS1 may overlap the entire active layer ACT of the driving transistor DT. For example, the first portion INS1A of the first insulating layer INS1 may overlap the channel region CH, the source region SR and the drain region DR of the driving transistor DT. Although FIG. 5 illustrates an embodiment in which the first portion INS1A of the first insulating layer INS1 has substantially the same width as the active layer ACT of the driving transistor DT, embodiments are not limited thereto. For example, the first portion INS1A of the first insulating layer INS1 may also extend to an area around the active layer ACT of the driving transistor DT in plan view.

In an embodiment, as illustrated in FIG. 6, the first portion INS1A of the first insulating layer INS1 may overlap a portion of the active layer ACT of the driving transistor DT which includes the channel region CH, and the second portion INS1B of the first insulating layer INS1 may overlap another portion (e.g., the source region SR and the drain region DR) of the active layer ACT of the driving transistor DT. Although FIG. 6 illustrates an embodiment in which the first portion INS1A of the first insulating layer INS1 overlaps the channel region CH of the driving transistor DT and does not overlap the source region SR and the drain region DR of the driving transistor DT, embodiments are not limited thereto. For example, the first portion INS1A of the first insulating layer INS1 may also be located under a portion of each of the source region SR and the drain region DR of the driving transistor DT.

In an embodiment, the second portion INS1B of the first insulating layer INS1 may be disposed under the active layer ACT of at least one pixel transistor PXT including at least one switching transistor ST disposed in each pixel area PXA. For example, the second portion INS1B of the first insulating layer INS1 may overlap at least a portion of the active layer ACT of the switching transistor ST illustrated in FIGS. 5 and 6. For example, the second portion INS1B of the first insulating layer INS1 may overlap a channel region CH included in the active layer ACT of the switching transistor ST and may or may not overlap a source region SR and/or a drain region DR included in the active layer ACT of the switching transistor ST.

In an embodiment, the second portion INS1B of the first insulating layer INS1 may overlap the entire active layer ACT of the switching transistor ST and may also extend to an area around the active layer ACT of the switching transistor ST in plan view. For example, the first portion INS1A of the first insulating layer INS1 may be disposed only around the driving transistor DT to partially or entirely overlap (or cover) a portion under the active layer ACT of the driving transistor DT of each pixel PX, and another portion of the first insulating layer INS1 excluding the portion where the first portion INS1A is located may be the second portion INS1B.

In an embodiment, the second insulating layer INS2 under the first insulating layer INS1 may include an insulating material suitable as a barrier material that can prevent the diffusion of oxygen or hydrogen. For example, the second insulating layer INS2 may be a silicon nitride layer including silicon nitride (SiNₓ). However, embodiments are not limited thereto, and the second insulating layer INS2 may also include other insulating materials that can appropriately block oxygen, hydrogen and/or moisture, in addition to silicon nitride (SiNₓ).

The second insulating layer INS2 may prevent or reduce the diffusion of oxygen injected into the first insulating layer INS1 to under the first insulating layer INS1. The second insulating layer INS2 may prevent or reduce the diffusion of hydrogen under the second insulating layer INS2 to above the second insulating layer INS. Accordingly, the oxygen concentration of the first insulating layer INS1 can be appropriately maintained, and the operating characteristics of transistors disposed on the first insulating layer INS1 can be improved or optimized.

Each of the pixel transistors PXT may include an active layer ACT disposed on the first insulating layer INS1 and a gate electrode GE overlapping a portion of the active layer ACT. The gate insulating layer GI may be disposed between the active layer ACT and the gate electrode GE of each of the pixel transistors PXT. In an embodiment, each of the pixel transistors PXT may further include at least one of a drain electrode DE electrically connected to the drain region DR of the active layer ACT and a source electrode SE electrically connected to the source region SR of the active layer ACT. For example, at least one pixel transistor PXT may not include the drain electrode DE and the source electrode SE, and the drain region DR and the source region SR of the active layer ACT may function as a drain electrode and a source electrode.

The active layers ACT of the pixel transistors PXT may be disposed on the first insulating layer INS1. For example, a semiconductor layer including the active layers ACT may be disposed on the first insulating layer INS1. The semiconductor layer may be overlapped by the gate insulating layer GI and the interlayer insulating layer ILD.

Each of the active layers ACT may include the channel region CH, the source region SR, and the drain region DR. The channel region CH may overlap the gate electrode GE in plan view and may be disposed between the source region SR and the drain region DR. The source region SR and the drain region DR may be located on both sides of the channel region CH and may be spaced apart from each other with the channel region CH therebetween. The source region SR and the drain region DR (or a portion of each of the source region SR and the drain region DR) may not overlap the gate electrode GE in plan view. The carrier concentration (e.g., electron concentration) of the source region SR and the drain region DR may be higher than the carrier concentration of the channel region CH.

In an embodiment, the active layers ACT of the pixel transistors PXT may include an oxide semiconductor. For example, the active layers ACT of the pixel transistors PXT may include an oxide semiconductor including at least one of indium (In), gallium (Ga), zinc (Zn), tin (Sn) and hafnium (Hf), or other oxide semiconductors. For example, the active layers ACT of the pixel transistors PXT may include at least one of zinc oxide (ZnO), zinc-tin oxide (ZTO), indium-zinc oxide (IZO), indium oxide (InO or In₂O₃), titanium oxide (TiO or TiO₂), indium-gallium oxide (IGO), indium-gallium-zinc oxide (IGZO), indium-gallium-tin oxide (IGTO), indium-zinc-tin oxide (IZTO) and indium-tin-gallium-zinc oxide (ITGZO), or other oxide semiconductors.

In embodiments, the active layers ACT of some transistors (e.g., at least a portion of each of the active layers ACT including the channel regions CH) among the transistors disposed in the panel circuit layer PCL, including the pixel transistors PXT, may be disposed on the first portion INS1A of the first insulating layer INS1. The active layers ACT of other transistors (e.g., at least a portion of each of the active layers ACT including the channel regions CH) among the transistors disposed in the panel circuit layer PCL may be disposed on the second portion INS1B of the first insulating layer INS1.

In the description of embodiments, a transistor in which a channel region CH of an active layer ACT is disposed on the first portion INS1A of the first insulating layer INS1 may also be referred to as a “first transistor T1.” A transistor in which a channel region CH of an active layer ACT is disposed on the second portion INS1B of the first insulating layer INS1 may also be referred to as a “second transistor T2.”

Each of the first transistor T1 and the second transistor T2 may include an active layer ACT and a gate electrode GE overlapping the active layer ACT (e.g., disposed on the gate insulating layer GI covering (or overlapping) a channel region CH of the active layer ACT). The active layer ACT and the gate electrode GE of the first transistor T1 may also be referred to as a “first active layer” and a “first gate electrode,” respectively. The active layer ACT and the gate electrode GE of the second transistor T2 may also be referred to as a “second active layer” and a “second gate electrode,” respectively. Each of the first transistor T1 and the second transistor T2 may further include at least one of a source electrode SE and a drain electrode DE, or a source region SR and a drain region DR may function as a source electrode and a drain electrode, respectively. In an embodiment, the first transistor T1 and the second transistor T2 may be oxide transistors. For example, the active layers ACT of the first transistor T1 and the second transistor T2 may include an oxide semiconductor.

In an embodiment, at least one first transistor T1 and at least one second transistor T2 may be disposed in each pixel area PXA. Accordingly, multiple first transistors T1 and multiple second transistors T2 may be disposed in the display area DA.

In an embodiment, the first transistors T1 may include the driving transistor DT of each pixel PX. For example, the channel region CH of the driving transistor DT may be disposed on the first portion INS1A of the first insulating layer INS1. The source region SR and the drain region DR of the driving transistor DT may be disposed on the first portion INS1A or the second portion INS1B of the first insulating layer INS1. Since the channel region CH of the driving transistor DT is disposed on the first portion INS1A of the first insulating layer INS1, an increase in a threshold voltage of the driving transistor DT (e.g., a positive shift of the threshold voltage) can be prevented or reduced. For example, the driving transistor DT may have a lower threshold voltage than a transistor having the same channel length as the driving transistor DT and disposed on the second portion INS1B of the first insulating layer INS1. Accordingly, the deterioration of the driving transistor DT can be improved, and the reliability of the driving transistor DT can be secured.

In an embodiment, the second transistors T2 may include at least one short-channel transistor included in each pixel PX. For example, at least one of the switching transistors ST of each pixel PX may be the second transistor T2. For example, the switching transistor ST illustrated in FIGS. 5 and 6 may correspond to the second transistor T2 and may be disposed on the second portion INS1B of the first insulating layer INS1. The channel region CH of the switching transistor ST may be disposed on the second portion INS1B of the first insulating layer INS1. The source region SR and the drain region DR of the switching transistor ST may be disposed on the first portion INS1A or the second portion INS1B of the first insulating layer INS1. Since the channel region CH of the switching transistor ST is disposed on the second portion INS1B of the first insulating layer INS1, a decrease in a threshold voltage of the switching transistor ST (e.g., a negative shift of the threshold voltage) can be prevented or reduced. For example, during a process of manufacturing the display panel 110, the amount of oxygen flowing from the second portion INS1B of the first insulating layer INS1 having a high oxygen concentration to the active layer ACT of the switching transistor ST may increase. Accordingly, the switching transistor ST may have a higher threshold voltage than a transistor having the same channel length as the switching transistor ST and disposed on the first portion INS1A of the first insulating layer INS1. Therefore, in case that the switching transistor ST is formed as a short-channel transistor, a roll-off phenomenon due to a short-channel effect can be prevented or improved, and the operating characteristics of the switching transistor ST can be secured. Leakage current through the switching transistor ST can be prevented or reduced. For example, the channel length of the switching transistor ST may be shorter than the channel length of the driving transistor DT. The switching transistor ST may have a high threshold voltage compared to its channel length and thus may exhibit stable operating characteristics.

The gate insulating layer GI may be disposed on the active layers ACT of the pixel transistors PXT. For example, the gate insulating layer GI may be disposed on a portion of each of the active layers ACT including the channel regions CH.

The gate insulating layer GI may include at least one inorganic insulating layer including an inorganic insulating material (e.g., silicon nitride (SiNₓ), silicon oxide (SiOₓ), silicon oxynitride (SiON), titanium oxide (TiOₓ), aluminum oxide (AlₓO_{y}), or other inorganic insulating materials).

In an embodiment, in each transistor area where a transistor is disposed, the gate insulating layer GI may be etched to cover (or overlap) a portion of the active layer ACT included in the transistor and expose another portion of the active layer ACT. For example, in an area where the driving transistor DT is disposed, the gate insulating layer GI may overlap the channel region CH of the active layer ACT included in the driving transistor DT and expose the source region SR and the drain region DR of the active layer ACT. In an area where the switching transistor ST is disposed, the gate insulating layer GI may overlap the channel region CH of the active layer ACT included in the switching transistor ST and expose the source region SR and the drain region DR of the active layer ACT.

Since the gate insulating layer GI exposes the source regions SR and the drain regions DR, the conductivity of the source regions SR and the drain regions DR can be increased appropriately and/or readily during the process of manufacturing the display panel 110. For example, due to oxygen vacancies created in the source regions SR and the drain regions DR in a process of etching the gate insulating layer GI to expose at least a portion of each of the source regions SR and the drain regions DR, the carrier concentration of the source regions SR and the drain regions DR may increase in a subsequent process (e.g., a process of forming the interlayer insulating layer ILD) in case that a separate doping process is not performed.

However, embodiments are not limited thereto. For example, the gate insulating layer GI may also entirely cover (or overlap) the active layers ACT of some or all of the transistors included in the panel circuit layer PCL, except for contact holes for connecting each transistor to other circuit elements or lines.

A second conductive layer (e.g., a gate conductive layer) including the gate electrodes GE of the pixel transistors PXT may be disposed on the gate insulating layer GI. For example, the gate electrode GE of the driving transistor DT may be disposed on the gate insulating layer GI covering (or overlapping) the channel region CH of the driving transistor DT. The gate electrode GE of the switching transistor ST may be disposed on the gate insulating layer GI covering (or overlapping) the channel region CH of the switching transistor ST. Each of the patterns of the second conductive layer including the gate electrodes GE may include at least one conductive material and may be composed of a single layer or multiple layers.

The interlayer insulating layer ILD may be disposed on the buffer layer BFL, the semiconductor layer including the active layers ACT, the gate insulating layer GI, and the second conductive layer including the gate electrodes GE. For example, the interlayer insulating layer ILD may be disposed on the buffer layer BFL to cover (or overlap) the semiconductor layer, the gate insulating layer GI, and the patterns of the second conductive layer. The interlayer insulating layer ILD may include at least one inorganic insulating layer including an inorganic insulating material.

A third conductive layer (e.g., a source-drain conductive layer) including the source electrodes SE and the drain electrodes DE of the pixel transistors PXT and/or conductive patterns electrically connected to at least some of the pixel transistors PXT may be disposed on the interlayer insulating layer ILD. For example, the third conductive layer may include the source electrode SE and the drain electrode DE of the driving transistor DT and the source electrode SE and the drain electrode DE of the switching transistor ST. Each of the patterns of the third conductive layer may include at least one conductive material and may be composed of a single layer or multiple layers.

The source electrode SE and the drain electrode DE of the driving transistor DT may penetrate the interlayer insulating layer ILD and be electrically connected to the source region SR and the drain region DR of the driving transistor DT, respectively. In an embodiment, the source electrode SE of the driving transistor DT may also penetrate the interlayer insulating layer ILD and the buffer layer BFL and be electrically connected to the bottom electrode BE of the driving transistor DT. The source electrode SE and the drain electrode DE of the switching transistor ST may penetrate the interlayer insulating layer ILD and be electrically connected to the source region SR and the drain region DR of the switching transistor ST, respectively.

The planarization layer VIA may be disposed on the pixel transistors PXT. For example, the planarization layer VIA may be disposed on the interlayer insulating layer ILD and the third conductive layer. The planarization layer VIA may include at least one organic insulating layer including an organic insulating material (e.g., acryl resin, epoxy resin, phenolic resin, polyamide resin, polyimide resin, or other organic insulating materials). The planarization layer VIA may include an inorganic insulating layer or may not include an inorganic insulating layer. A surface (e.g., an upper surface) of the planarization layer VIA may be substantially flat.

The light emitting element layer LEL may be disposed on the panel circuit layer PCL. For example, the light emitting element layer LEL may be disposed on the planarization layer VIA and may be located at least in the display area DA.

The light emitting element layer LEL may include a light emitting element ED of each pixel PX. For example, the light emitting element layer LEL may include a pixel defining layer PDL (also referred to as a “bank”) that defines an emission area of each pixel PX and a light emitting element ED located in each emission area. In an embodiment, the light emitting element layer LEL may further include a spacer SPC disposed on a portion of the pixel defining layer PDL.

Each light emitting element ED may include a first electrode ET1 located in an emission area and a light emitting layer EML and a second electrode ET2 sequentially disposed on the first electrode ET1. The first electrode ET1 of each light emitting element ED may penetrate the planarization layer VIA and be electrically connected to at least one pixel transistor PXT (e.g., the driving transistor DT) included in a corresponding pixel PX.

The first electrode ET1 of each light emitting element ED may be a single-layer or multilayer electrode including at least one conductive material. In an embodiment, the display panel 110 may be a top emission display panel, and the first electrode ET1 may include a reflective electrode layer having high reflectivity.

The light emitting layer EML of each light emitting element ED may include a high-molecular material or a low-molecular material. Light emitted from the light emitting layer EML may contribute to image display.

Although FIGS. 5 and 6 illustrate the display panel 110 in which the light emitting layer EML of a light emitting element ED is individually formed in each pixel area PXA, embodiments are not limited thereto. For example, the display panel 110 may also include light emitting elements having a tandem structure that includes the light emitting layer EML formed as a common layer over the entire display area DA.

The second electrode ET2 of each light emitting element ED may include a conductive material. In an embodiment, the second electrode ET2 may be a common layer formed over the entire display area DA to cover (or overlap) the light emitting layer EML and the pixel defining layer PDL. In an embodiment, the display panel 110 may be a top emission display panel, and the second electrode ET2 may include a transparent or translucent electrode layer.

The pixel defining layer PDL may have an opening corresponding to each emission area and may surround each emission area. For example, the pixel defining layer PDL may be formed to cover (or overlap) an edge portion of the first electrode ET1 of each light emitting element ED and may include an opening exposing another portion of the first electrode ET1. An area where the exposed first electrode ET1 and the light emitting layer EML overlap may be the emission area of each pixel PX. In an embodiment, the pixel defining layer PDL may include at least one organic insulating layer including an organic insulating material.

The spacer SPC may be disposed on a portion of the pixel defining layer PDL. The spacer SPC may include at least one organic insulating layer including an organic insulating material. The spacer SPC and the pixel defining layer PDL may include the same material or a different material. The pixel defining layer PDL and the spacer SPC may be sequentially formed through separate mask processes or may be integral with each other by being simultaneously formed using a halftone mask.

The encapsulation layer ENL may be disposed on the light emitting element layer LEL. The encapsulation layer ENL may cover (or overlap) the light emitting element layer LEL in the display area DA and may extend to the non-display area NDA to contact the panel circuit layer PCL. The encapsulation layer ENL may block the penetration of oxygen or moisture into the light emitting element layer LEL and mitigate electrical and/or physical impacts on the panel circuit layer PCL and the light emitting element layer LEL.

In an embodiment, the encapsulation layer ENL may include a first encapsulation layer ENL1, a second encapsulation layer ENL2, and a third encapsulation layer ENL3 sequentially disposed on the light emitting element layer LEL. Each of the first encapsulation layer ENL1 and the third encapsulation layer ENL3 may be an inorganic encapsulation layer including an inorganic material. The second encapsulation layer ENL2 may be an organic encapsulation layer including an organic material.

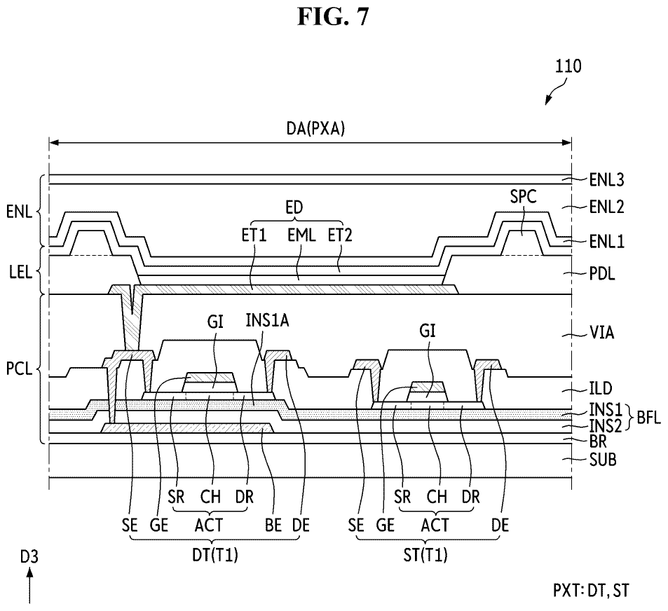

FIG. 7 is a schematic cross-sectional view of a display panel 110 according to an embodiment. FIG. 7 shows an embodiment different from the embodiments of FIGS. 5 and 6 in relation to a first insulating layer INS1.

Referring to FIG. 7, a first portion INS1A of the first insulating layer INS1 may be disposed in the entire display area DA. For example, the oxygen concentration of the first insulating layer INS1 may be uniform throughout the display area DA. Active layers ACT of a driving transistor DT and a switching transistor ST of each pixel PX may be disposed on the first portion INS1A of the first insulating layer INS1. First transistors T1 may include the driving transistor DT and the switching transistor ST of each pixel PX.

In an embodiment, a second portion INS1B of the first insulating layer INS1 may be disposed in at least a portion of the non-display area NDA illustrated in FIGS. 1 and 2. For example, the second portion INS1B of the first insulating layer INS1 may be disposed in a portion of a circuit area where at least one built-in circuit (such as the first driver 120 or the demultiplexer 150) that can be disposed in the display panel 110 is located or may be disposed in the entire circuit area. The second portion INS1B of the first insulating layer INS1 may be disposed in a portion of the non-display area NDA or may be disposed in the entire non-display area NDA.

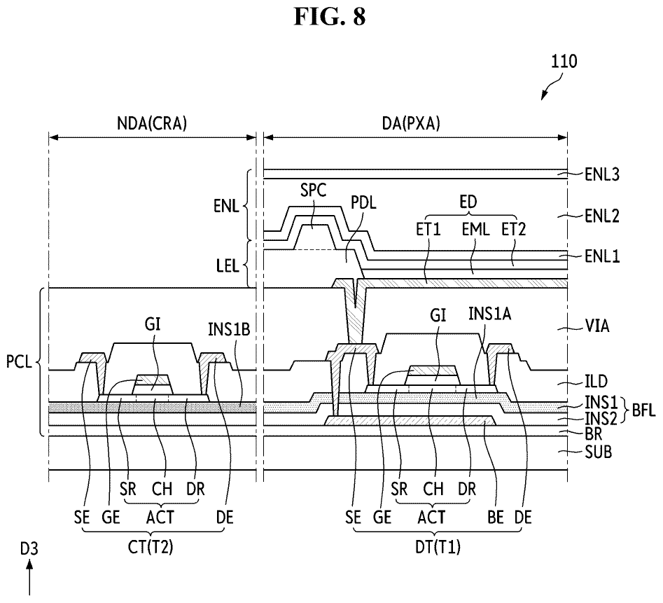

FIG. 8 is a schematic cross-sectional view of a display panel 110 according to an embodiment. For example, FIG. 8 partially illustrates a display area DA and a non-display area NDA of the display panel 110.

Referring to FIG. 8 in addition to FIGS. 1 through 7, the display panel 110 may further include a circuit transistor CT disposed in the non-display area NDA. FIG. 8 illustrates a circuit transistor CT disposed in the non-display area NDA and formed in a panel circuit layer PCL together with pixel transistors PXT. The circuit transistor CT of FIG. 8 may be disposed in a circuit area CRA of the non-display area NDA. The circuit area CRA may be an area where at least one built-in circuit that can be formed inside the display panel 110 together with pixels PX is formed. For example, the circuit area CRA may include an area where the first driver 120 and the demultiplexer 150 of FIGS. 1 and 2 are disposed. The circuit transistor CT of FIG. 8 may be included in the first driver 120 or the demultiplexer 150 and may be a short-channel transistor that performs a switching operation.

FIG. 8 illustrates a driving transistor DT disposed in a pixel area PXA as an example of a transistor that can be disposed in the display area DA. For example, the driving transistor DT of FIG. 8 may be the driving transistor DT according to the embodiments of FIGS. 5 through 7. FIG. 8 shows an embodiment in which a first portion INS1A of a first insulating layer INS1 is disposed in the entire pixel area PXA (or display area DA) as in FIG. 7. However, embodiments are not limited thereto. For example, as in the embodiments of FIGS. 5 and 6, the first portion INS1A of the first insulating layer INS1 may be disposed in a portion of each pixel area PXA of the display area DA, and a second portion INS1B of the first insulating layer INS1 may be disposed in another portion of each pixel area PXA.

In an embodiment, the first driver 120 may include multiple short-channel transistors formed to have substantially the same material and/or structure as the circuit transistor CT of FIG. 8. For example, some or all of the transistors included in the first driver 120 and performing a switching operation may be formed to have substantially the same material and/or structure as the circuit transistor CT of FIG. 8.

In an embodiment, the demultiplexer 150 may include multiple short-channel transistors formed to have substantially the same material and/or structure as the circuit transistor CT of FIG. 8. For example, some or all of the transistors (e.g., the switching elements of the demultiplexer 150) included in the demultiplexer 150 and performing a switching operation may be formed to have substantially the same material and/or structure as the circuit transistor CT of FIG. 8.

The circuit transistor CT may include an active layer ACT disposed on the first insulating layer INS1 and a gate electrode GE overlapping the active layer ACT. A gate insulating layer GI may be disposed between the active layer ACT and the gate electrode GE of the circuit transistor CT. In an embodiment, the gate insulating layer GI may be disposed only on a portion of the active layer ACT of the circuit transistor CT. For example, the gate insulating layer GI may cover (or overlap) a channel region CH included in the active layer ACT of the circuit transistor CT and expose a source region SR and a drain region DR included in the active layer ACT. However, embodiments are not limited thereto. For example, the gate insulating layer GI may also cover (or overlap) the entire active layer ACT of the circuit transistor CT.

In an embodiment, the circuit transistor CT may further include at least one of a source electrode SE electrically connected to the source region SR and a drain electrode DE electrically connected to the drain region DR. In an embodiment, the circuit transistor CT may not include at least one of the source electrode SE and the drain electrode DE, and the source region SR and the drain region DR of the circuit transistor CT may function as a source electrode and a drain electrode.

In an embodiment, the circuit transistor CT and the pixel transistors PXT may be formed simultaneously. Accordingly, the structure of the display panel 110 can be simplified, and the manufacturing efficiency of the display panel 110 can be increased.

For example, the active layer ACT of the circuit transistor CT may be formed at the same time as active layers ACT of the pixel transistors PXT using the same material. Accordingly, the active layer ACT of the circuit transistor CT and the active layers ACT of the pixel transistors PXT may be disposed on a same layer in the panel circuit layer PCL and may include the same material. For example, the active layer ACT of the circuit transistor CT may be disposed on the first insulating layer INS1 and may include an oxide semiconductor (e.g., an oxide semiconductor included in the active layers ACT of the pixel transistors PXT). In an embodiment, the active layer ACT of at least one pixel transistor PXT (e.g., the active layer ACT of the driving transistor DT included in each pixel PX) and the active layer ACT of the circuit transistor CT may have different characteristics (e.g., mobility, oxygen concentration, and/or carrier concentration).

In an embodiment, the gate insulating layer GI disposed on the active layer ACT of the circuit transistor CT may be formed at the same time as a gate insulating layer GI disposed on the active layers ACT of the pixel transistors PXT using the same material. For example, the gate insulating layer GI disposed on the active layer ACT of the circuit transistor CT and the gate insulating layer GI disposed on the active layers ACT of the pixel transistors PXT may be formed on a same layer and may include the same insulating material.

In an embodiment, the gate electrode GE of the circuit transistor CT may be formed at the same time as gate electrodes GE of the pixel transistors PXT using the same material. For example, the gate electrode GE of the circuit transistor CT and the gate electrodes GE of the pixel transistors PXT may be disposed on their respective gate insulating layers GI and may include the same conductive material.

In an embodiment, the source electrode SE and/or the drain electrode DE of the circuit transistor CT may be formed at the same time as source electrodes SE and/or drain electrodes DE of the pixel transistors PXT using the same material. For example, the source electrode SE and/or the drain electrode DE of the circuit transistor CT and the source electrodes SE and/or the drain electrodes DE of the pixel transistors PXT may be disposed on an interlayer insulating layer ILD and may include the same conductive material.

In an embodiment, the circuit transistor CT may be a second transistor T2 disposed on the second portion INS1B of the first insulating layer INS1. For example, at least a portion of the active layer ACT including the channel region CH of the circuit transistor CT may be disposed on the second portion INS1B of the first insulating layer INS1.

In an embodiment, the second portion INS1B of the first insulating layer INS1 may be disposed in a portion of the circuit area CRA or may be disposed in the entire circuit area CRA. For example, the first portion INS1A of the first insulating layer INS1 may be disposed in the entire display area DA, and the second portion INS1B of the first insulating layer INS1 may be disposed in the entire non-display area NDA. Accordingly, oxygen concentration in each portion of the first insulating layer INS1 can be controlled more appropriately or readily.

Since the channel region CH of the circuit transistor CT is disposed on the second portion INS1B of the first insulating layer INS1, a decrease in a threshold voltage of the circuit transistor CT (e.g., a negative shift of the threshold voltage) can be prevented or reduced. For example, during a process of manufacturing the display panel 110, the amount of oxygen flowing from the second portion INS1B of the first insulating layer INS1 having a high oxygen concentration to the active layer ACT of the circuit transistor CT may increase. Accordingly, the circuit transistor CT may have a high threshold voltage compared with a transistor having the same channel length as the circuit transistor CT and disposed on the first portion INS1A of the first insulating layer INS1. Therefore, in case that the circuit transistor CT is formed as a short-channel transistor, a roll-off phenomenon due to a short-channel effect can be prevented or improved, and the operating characteristics of the circuit transistor CT can be secured. Leakage current through the circuit transistor CT can be prevented or reduced, thereby improving the operating characteristics of a built-in circuit (e.g., the first driver 120 and/or the demultiplexer 150). In an embodiment, a channel length of the circuit transistor CT may be shorter than a channel length of the driving transistor DT disposed in the pixel area PXA. However, embodiments are not limited thereto. The circuit transistor CT may have a high threshold voltage compared to its channel length and thus may exhibit stable operating characteristics.

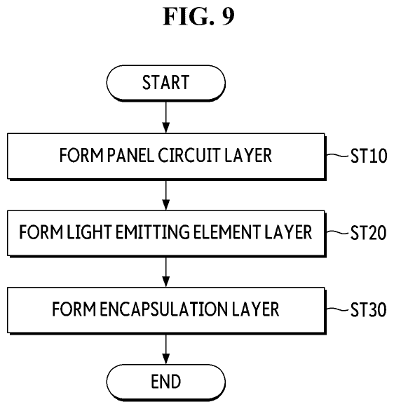

FIG. 9 is a flowchart illustrating a method of manufacturing a display device according to an embodiment. For example, FIG. 9 is a schematic cross-sectional view illustrating a method of manufacturing a display panel 110 including a panel circuit layer PCL, a light emitting element layer LEL, and an encapsulation layer ENL as in the embodiments of FIGS. 5 through 8.

Referring to FIG. 9 in addition to FIGS. 1 through 8, the panel circuit layer PCL may be formed (operation ST10). For example, a substrate SUB including a display area DA and a non-display area NDA may be prepared, and the panel circuit layer PCL may be formed on the substrate SUB. The forming of the panel circuit layer PCL may include forming pixel transistors PXT in the display area DA. In an embodiment, the forming of the panel circuit layer PCL may further include forming circuit transistors CT in the non-display area NDA. In an embodiment, the pixel transistors PXT and the circuit transistors CT may be formed substantially simultaneously. A method of forming the pixel transistors PXT and the circuit transistors CT will be described in detail later.

Next, the light emitting element layer LEL may be formed (operation ST20). The light emitting element layer LEL may be formed on the panel circuit layer PCL and may be disposed in the display area DA. The forming of the light emitting element layer LEL may include forming a light emitting element ED in each pixel area PXA. The forming of the light emitting element layer LEL may further include forming a pixel defining layer PDL and a spacer SPC.

Next, the encapsulation layer ENL may be formed (operation ST30). The encapsulation layer ENL may be formed on the light emitting element layer LEL. The encapsulation layer ENL may be formed at least in the display area DA and may cover (or overlap) the light emitting elements ED of pixels PX. In an embodiment, the encapsulation layer ENL may also be formed in a portion of the non-display area NDA. For example, an end of the encapsulation layer ENL may be located in a portion of the non-display area NDA which is immediately adjacent to the display area DA. The encapsulation layer ENL may or may not overlap a circuit area CRA. For example, the encapsulation layer ENL may cover (or overlap) at least some of the circuit transistors CT disposed in the circuit area CRA or may not cover (or overlap) the circuit transistors CT.

Through the above-described process, the display panel 110 including the panel circuit layer PCL, the light emitting element layer LEL, and the encapsulation layer ENL may be manufactured.

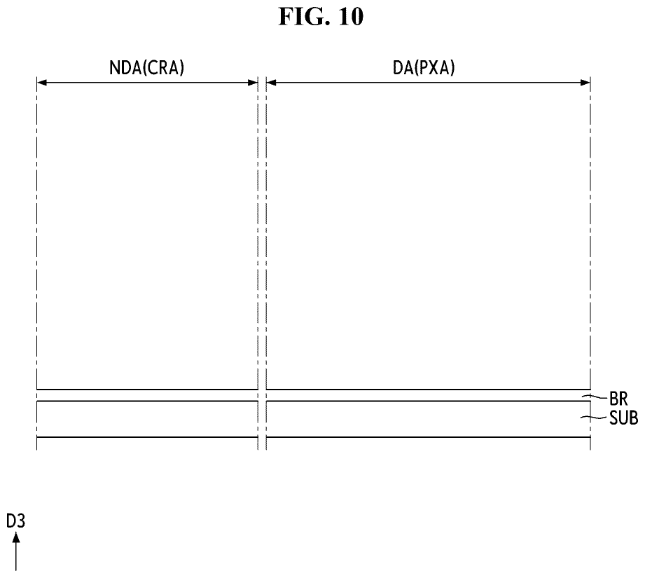

FIGS. 10 through 22 are schematic cross-sectional views illustrating a method of manufacturing a display device according to an embodiment. For example, FIGS. 10 through 22 sequentially illustrate manufacturing operations for forming a panel circuit layer PCL of a display panel 110 according to an embodiment, and the manufacturing operations of FIGS. 10 through 22 may be included in the operation ST10 of FIG. 9.

FIGS. 10 through 22 illustrate a process of forming the panel circuit layer PCL according to the embodiment of FIG. 8. However, as described above, positions (or boundaries) or sizes (e.g., areas) of a first portion INS1A and a second portion INS1B of a first insulating layer INS1 may vary according to embodiments. For example, FIGS. 10 through 22 disclose an embodiment in which the panel circuit layer PCL is formed in a structure in which the first portion INS1A and the second portion INS1B of the first insulating layer INS1 are disposed entirely over a display area DA and a non-display area NDA, respectively. However, embodiments are not limited thereto. For example, as in the embodiments of FIGS. 5 and 6, the first portion INS1A and the second portion INS1B of the first insulating layer INS1 may also be formed together in each pixel area PXA or the display area DA including the pixel areas PXA. The panel circuit layer PCL according to the embodiments of FIGS. 5 and 6 may be formed using substantially the same or similar method as the manufacturing method according to the embodiment of FIGS. 10 through 22, except for the positions or boundaries of the first portion INS1A and the second portion INS1B of the first insulating layer INS1.

Referring to FIG. 10, a substrate SUB including a display area DA and a non-display area NDA may be prepared, and a barrier layer BR may be formed on the substrate SUB. The barrier layer BR may be formed by a process of forming an insulating layer including an insulating material (e.g., an inorganic insulating material) above. In case that the panel circuit layer PCL does not include the barrier layer BR, the forming of the barrier layer BR may be omitted.

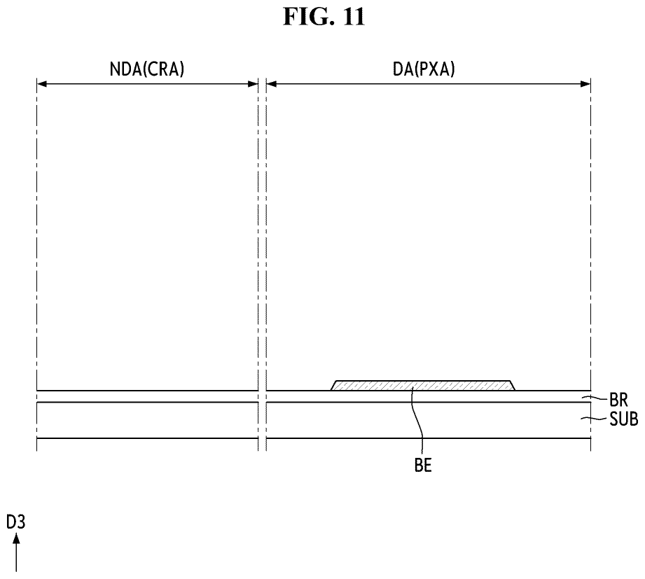

Referring to FIG. 11, a bottom electrode BE may be formed on the barrier layer BR. In case that the panel circuit layer PCL does not include the barrier layer BR, the bottom electrode BE may be formed on (e.g., directly on) the substrate SUB. In an embodiment, the bottom electrode BE may be formed in each pixel area PXA defined in the display area DA. For example, the bottom electrode BE may be formed in an area where a driving transistor DT is to be formed in each pixel area PXA. In case that the panel circuit layer PCL does not include the bottom electrode BE, the forming of the bottom electrode BE may be omitted.

The bottom electrode BE may be formed by a process of forming a conductive layer including at least one conductive material above and a process of patterning the conductive layer. In an embodiment, the process of patterning the conductive layer may include a photoresist process and an etching process. For example, the process of patterning the conductive layer may include a photoresist process for forming a photoresist pattern needed to etch the conductive layer in a shape corresponding to the bottom electrode BE, etc. and an etching process for forming the bottom electrode BE by etching the conductive layer using the photoresist pattern as a mask.

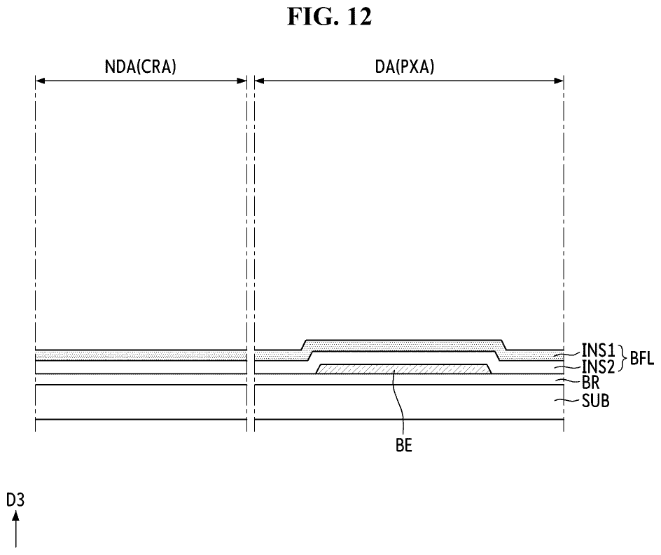

Referring to FIG. 12, a buffer layer BFL may be formed on the bottom electrode BE and the barrier layer BR (or the substrate SUB). The buffer layer BFL may be formed by a process of forming an insulating layer including at least one insulating material (e.g., an inorganic insulating material) above.

In an embodiment, the buffer layer BFL may be formed at least as a double layer including the first insulating layer INS1 and a second insulating layer INS2. For example, the second insulating layer INS2 may be formed on patterns of a first conductive layer and the barrier layer BR, and the first insulating layer INS1 may be formed on the second insulating layer INS2.

The second insulating layer INS2 may be formed by a process of forming an insulating layer including an insulating material above, for example, silicon nitride (SiNₓ). The first insulating layer INS1 may be formed by a process of forming an insulating layer including an insulating material above, for example, silicon oxide (SiOₓ). Accordingly, the second insulating layer INS2 may include silicon nitride, and the first insulating layer INS1 may include silicon oxide. However, the material of each of the first insulating layer INS1 and the second insulating layer INS2 may vary according to embodiments.

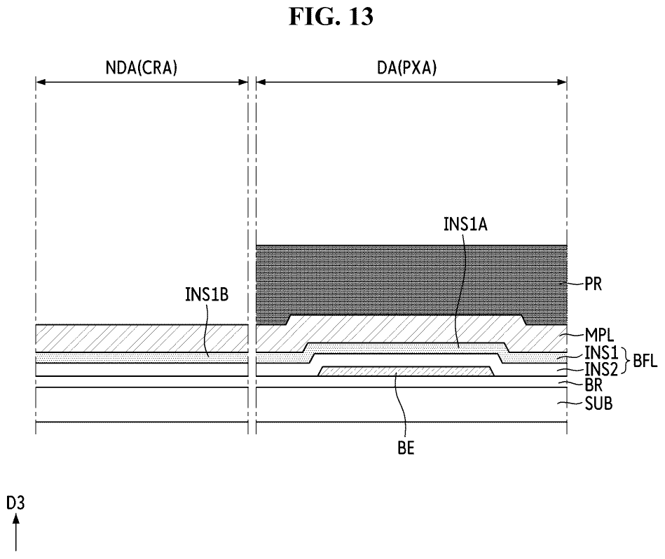

Referring to FIGS. 13 through 15, oxygen (O) may be injected (or supplied) into a portion of the first insulating layer INS1 to differentiate the oxygen concentration of each portion of the first insulating layer INS1. For example, the oxygen concentration of the first portion INS1A of the first insulating layer INS1 and the oxygen concentration of the second portion INS1B of the first insulating layer INS1 may be differentiated by injecting oxygen (O) into a portion of the first insulating layer INS1 which corresponds to a position where the second portion INS1B is to be formed.

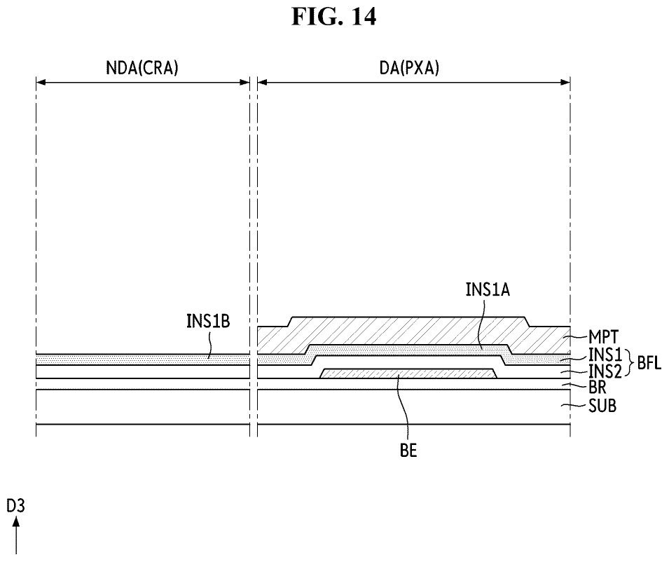

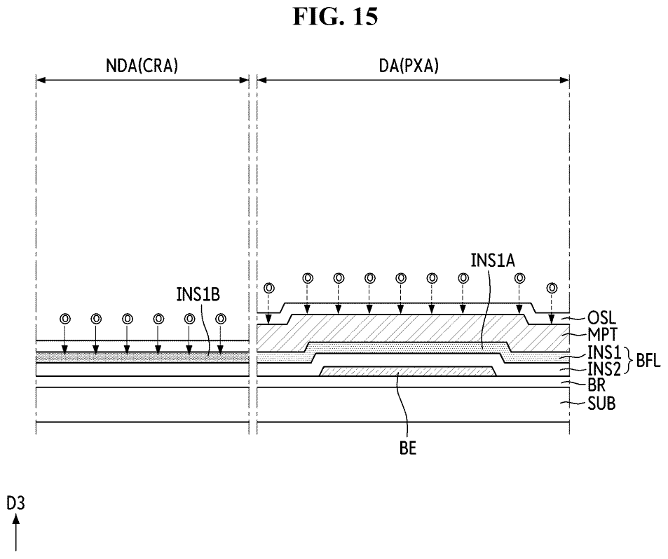

In an embodiment, the injecting of the oxygen (O) into the portion of the first insulating layer INS1 may include exposing a portion of the first insulating layer INS1 set as the second portion INS1B (e.g., a portion to be formed as the second portion INS1B of the first insulating layer INS1) and forming a mask pattern MPT on another portion of the first insulating layer INS1 set as the first portion INS1A (e.g., a portion to be formed as the first portion INS1A of the first insulating layer INS1) as illustrated in FIGS. 13 and 14 and differentiating the oxygen concentrations of the first portion INS1A and the second portion INS1B by forming an oxide semiconductor layer OSL on the first insulating layer INS1 and the mask pattern MPT as illustrated in FIG. 15.

For example, first, as illustrated in FIG. 13, a mask layer MPL for forming the mask pattern MPT may be formed on the entire surface of the first insulating layer INS1, and a photoresist pattern PR may be formed on a portion of the mask layer MPL which corresponds to a position where the mask pattern MPT is to be disposed. The mask layer MPL may include a barrier material that can block the inflow or diffusion of oxygen. For example, the mask layer MPL may include a metal suitable for preventing diffusion, such as titanium (Ti) or molybdenum (Mo), or may include other barrier materials.

Next, the mask pattern MPT of FIG. 14 may be formed by etching the mask layer MPL using the photoresist pattern PR as a mask. The photoresist pattern PR may be removed after the etching of the mask layer MPL.

Next, as illustrated in FIG. 15, the oxide semiconductor layer OSL (e.g., a sacrificial layer for oxygen injection) may be formed on the first insulating layer INS1 and the mask pattern MPT. In this process, oxygen (O) may be injected into a portion (e.g., the second portion INS1B) of the first insulating layer INS1 which is not covered with (or not overlapped by) the mask pattern MPT. The injection of the oxygen (O) into another portion (e.g., the first portion INS1A) of the first insulating layer INS1 which is covered with (or overlapped by) the mask pattern MPT may be substantially blocked by the mask pattern MPT. Accordingly, the oxygen concentrations of the first portion INS1A and the second portion INS1B of the first insulating layer INS1 may become different. For example, the first portion INS1A of the first insulating layer INS1 covered with (or overlapped by) the mask pattern MPT may be a portion including a low concentration of oxygen (O), and the second portion INS1B of the first insulating layer INS1 not covered with (or overlapped by) the mask pattern MPT may be an oxygen-excessive region including a high concentration of oxygen (O).

In an embodiment, after the oxide semiconductor layer OSL is formed, heat treatment may be performed to inject more oxygen (O) into the second portion INS1B of the first insulating layer INS1. Accordingly, the oxygen concentration of the second portion INS1B of the first insulating layer INS1 can be increased more appropriately or readily. The heat treatment process may be optionally performed and can be omitted.

In an embodiment, a process margin may be set in consideration of the diffusion of oxygen (O) that may occur at a boundary between the first portion INS1A and the second portion INS1B, and the mask pattern MPT may be extended by an amount corresponding to the process margin. Accordingly, the oxygen concentration of the first insulating layer INS1 may be appropriately differentiated according to regions set as the first portion INS1A and the second portion INS1B.

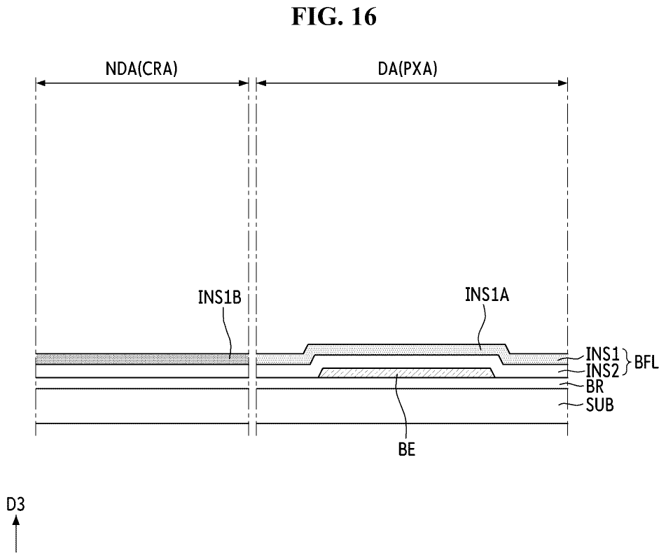

Referring to FIG. 16, after the oxygen concentrations of the first portion INS1A and the second portion INS1B of the first insulating layer INS1 are differentiated, the mask pattern MPT and the oxide semiconductor layer OSL may be removed.

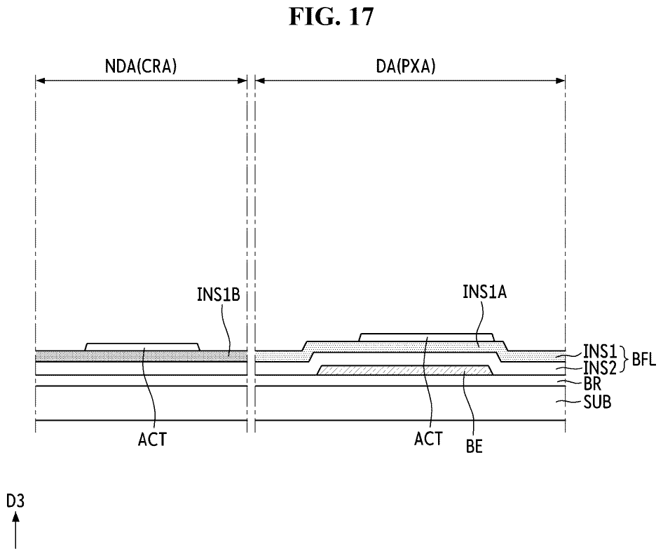

Referring to FIGS. 17 through 21, a first transistor T1 and a second transistor T2 may be formed on the first portion INS1A and the second portion INS1B of the first insulating layer INS1, respectively. For example, a driving transistor DT of a pixel PX may be formed on the first portion INS1A of the first insulating layer INS1, and a circuit transistor CT may be formed on the second portion INS1B of the first insulating layer INS1.

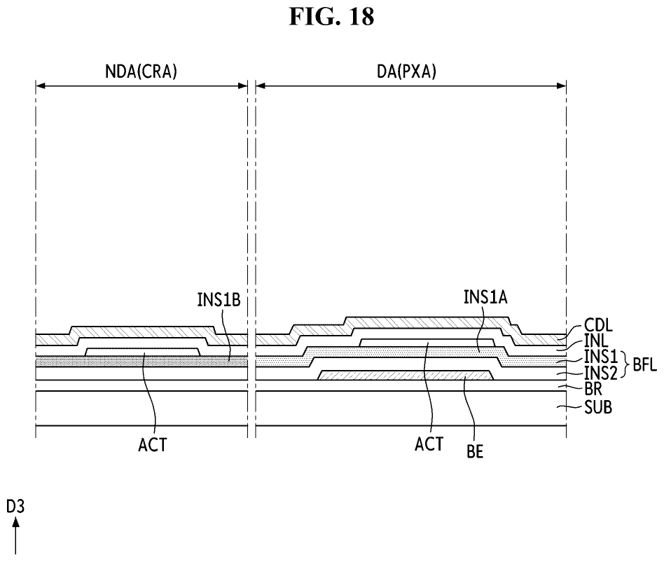

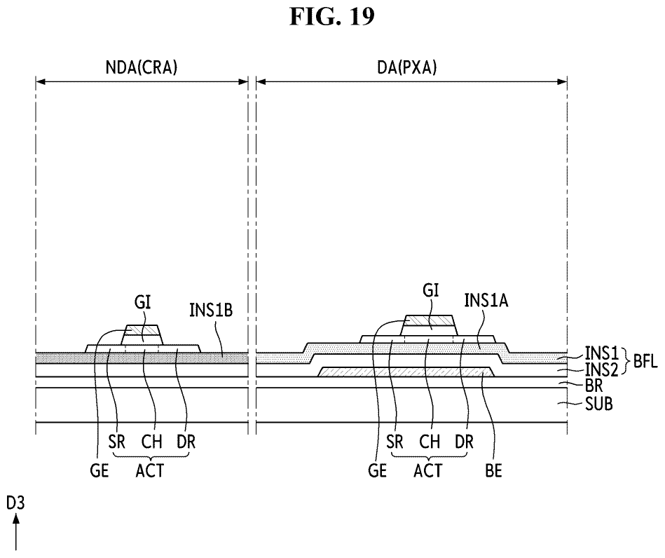

In an embodiment, the forming of the first transistor T1 and the second transistor T2 may include forming active layers ACT (active layers ACT of the first transistor T1 and the second transistor T2) on the first insulating layer INS1 as illustrated in FIG. 17 and forming a gate insulating layer GI and gate electrodes GE (gate electrodes GE of the first transistor T1 and the second transistor T2) on the active layers ACT as illustrated in FIGS. 18 and 19. In an embodiment, the forming of the first transistor T1 and the second transistor T2 may further include forming an interlayer insulating layer ILD, source electrodes SE and drain electrodes DE (source electrodes SE and drain electrodes DE of the first transistor T1 and the second transistor T2) on the gate insulating layer GI and the gate electrodes GE as illustrated in FIGS. 18 and 19.

For example, first, as illustrated in FIG. 17, the active layer ACT of the first transistor T1 and the active layer ACT of the second transistor T2 may be formed on the first portion INS1A and the second portion INS1B of the first insulating layer INS1, respectively. The active layers ACT of the first transistor T1 and the second transistor T2 may be made of a material above. For example, each active layer ACT including an oxide semiconductor may be formed by performing a process of forming a semiconductor layer including at least one oxide semiconductor above and a process of patterning the semiconductor layer (e.g., a patterning process including a photoresist process and an etching process).

Next, as illustrated in FIGS. 18 and 19, an insulating layer INL and a conductive layer CDL may be formed on the first insulating layer INS1 and the active layers ACT and then may be patterned to form the gate insulating layer GI and the gate electrode GE in each transistor area. For example, as illustrated in FIG. 18, the insulating layer INL and the conductive layer CDL may be sequentially formed on the first insulating layer INS1 and the active layers ACT. The insulating layer INL may be formed by a process of forming an insulating layer including at least one insulating material (e.g., an inorganic insulating material) above as the material of the gate insulating layer GI. The conductive layer CDL may be formed by a process of forming a conductive layer including at least one conductive material above. Next, the insulating layer INL and the conductive layer CDL may be patterned to form the gate insulating layer GI and the gate electrode GE on a portion (e.g., a portion where a channel region CH of each transistor is to be formed, including a central portion) of each of the active layers ACT disposed on the first portion INS1A and the second portion INS1B of the first insulating layer INS1. In an embodiment, the insulating layer INL and the conductive layer CDL may be patterned substantially simultaneously (or sequentially) by etching the insulating layer INL and the conductive layer CDL substantially simultaneously (or sequentially) using a mask (e.g., a mask formed in a photoresist process). Accordingly, each gate insulating layer GI and the gate electrode GE on the gate insulating layer GI may be formed in shapes and sizes corresponding to each other.

In the process of etching the insulating layer INL to form the gate insulating layer GI, the characteristics of each active layer ACT may be changed such that each active layer ACT has different characteristics in each portion. Accordingly, each active layer ACT may be divided into multiple regions having different characteristics.

For example, oxygen vacancies may be created in an oxide semiconductor that forms each active layer ACT due to an etching gas or the like in a portion not overlapping the gate insulating layer GI and the gate electrode GE. Accordingly, each active layer ACT may be divided into multiple regions (e.g., a channel region CH, a source region SR, and a drain region DR) having different characteristics. In an embodiment, oxygen vacancies may be created primarily in a portion (e.g., the source region SR and the drain region DR) of each active layer ACT which does not overlap the gate insulating layer GI and the gate electrode GE.

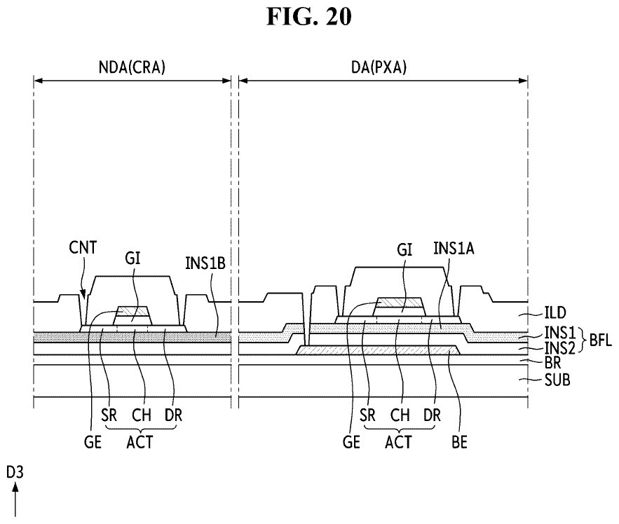

Next, as illustrated in FIG. 20, the interlayer insulating layer ILD may be formed on the first insulating layer INS1, the active layers ACT, the gate insulating layer GI, and the gate electrodes GE. The interlayer insulating layer ILD may be formed by a process of forming an insulating layer including at least one insulating material (e.g., an inorganic insulating material) above.

Hydrogen may be introduced into the active layers ACT during the process of forming the interlayer insulating layer ILD and/or a heat treatment process before and after the process. For example, hydrogen may be introduced into the source regions SR and the drain regions DR of the active layers ACT to increase carrier concentration. Accordingly, the conductivity of the source regions SR and drain regions DR may be increased.

After the interlayer insulating layer ILD is formed, multiple contact holes CNT may be formed in the interlayer insulating layer ILD. For example, contact holes CNT that partially expose the source region SR and the drain region DR of each of the active layers ACT may be formed by an etching process using a mask. In an embodiment, in case that the driving transistor DT is formed such that the source electrode SE of the driving transistor DT is connected to the bottom electrode BE, a contact hole CNT may also be formed to penetrate the interlayer insulating layer ILD, the first insulating layer INS1 and the second insulating layer INS2 and expose a portion of the bottom electrode BE.

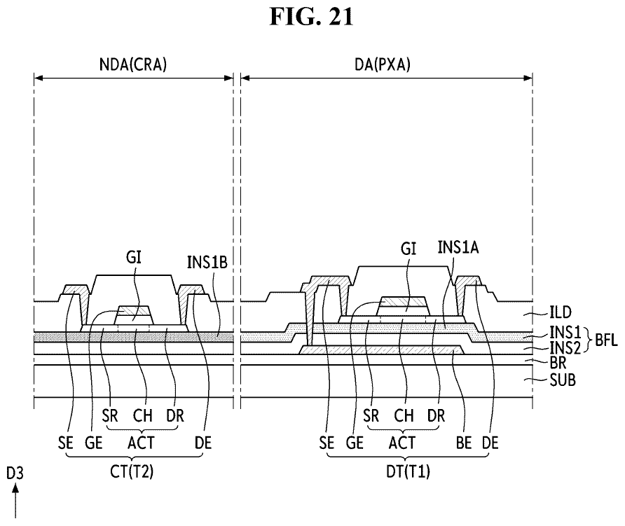

Next, as illustrated in FIG. 21, the source electrodes SE and the drain electrodes DE of the first transistor T1 and the second transistor T2 (or conductive patterns electrically connected to the first transistor T1 and/or the second transistor T2) may be formed on the interlayer insulating layer ILD. The source electrodes SE and the drain electrodes DE may be formed by a process of forming a conductive layer including at least one conductive material above and a process of patterning the conductive layer. Accordingly, the first transistor T1 and the second transistor T2 may be formed.

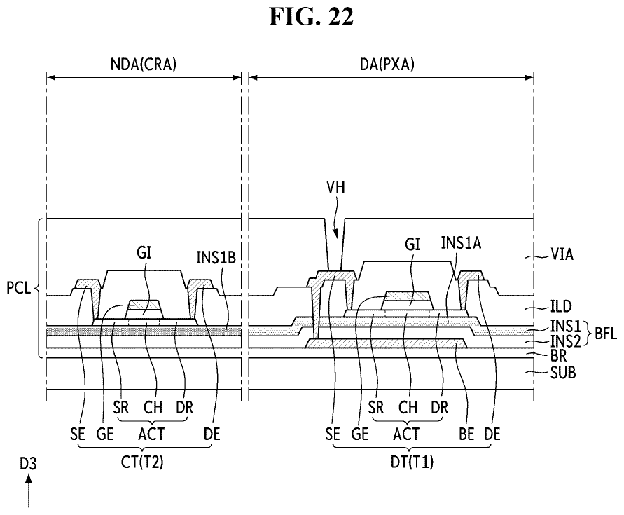

Referring to FIG. 22, a planarization layer VIA may be formed on the source electrodes SE and the drain electrodes DE (or the conductive patterns) of the first transistor T1 and the second transistor T2 and the interlayer insulating layer ILD. The planarization layer VIA may be formed by a process of forming an insulating layer including at least one organic insulating material above.

After the planarization layer VIA is formed, at least one via hole VH may be formed in the planarization layer VIA in each pixel area PXA. For example, the via hole VH may be formed to expose the source electrode SE of the driving transistor DT disposed in each pixel area PXA. Through the via hole VH, each light emitting element ED (e.g., the light emitting element ED of FIGS. 5 through 8) formed on the panel circuit layer PCL in a subsequent process may be electrically connected to the driving transistor DT of a corresponding pixel PX.

Through the above-described process, the panel circuit layer PCL of the display panel 110 according to the embodiment may be formed. In case that the display panel 110 includes a light emitting element layer LEL and an encapsulation layer ENL disposed on the panel circuit layer PCL as in the embodiments of FIGS. 5 through 8, the light emitting element layer LEL and the encapsulation layer ENL may be sequentially formed on the panel circuit layer PCL. Through the above-described process, the display panel 110 and a display device 100 including the same according to embodiments may be manufactured.

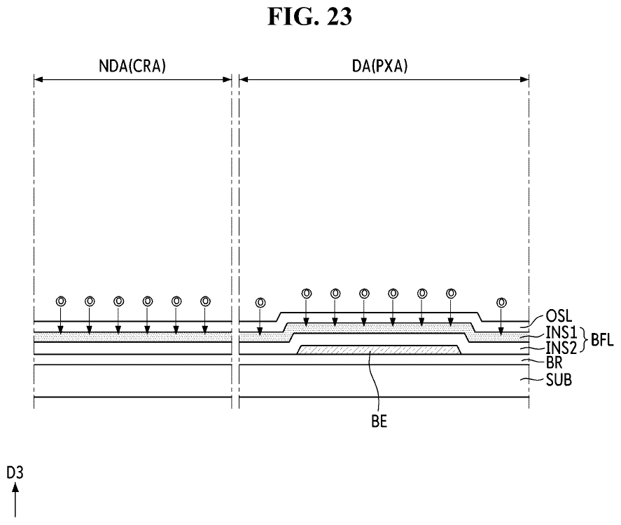

FIGS. 23 through 25 are schematic cross-sectional views illustrating a method of manufacturing a display device according to an embodiment. For example, FIGS. 23 through 25 show an embodiment different from the embodiment of FIGS. 13 through 15 in relation to a method of differentiating the oxygen concentration of each portion of a first insulating layer INS1 by injecting (or supplying) oxygen into a portion of the first insulating layer INS1.

Referring to FIGS. 23 through 25, it is possible to differentiate the oxygen concentrations of a first portion INS1A and a second portion INS1B of the first insulating layer INS1 without forming the mask layer MPL of FIGS. 13 through 15 and the mask pattern MPT formed from the mask layer MPL. For example, after a barrier layer BR, a bottom electrode BE and a buffer layer BFL are formed on a substrate SUB as illustrated in FIGS. 10 through 12, an oxide semiconductor layer OSL may be formed on (e.g., directly on) the first insulating layer INS1 of the buffer layer BFL as illustrated in FIG. 23. In this process, oxygen (O) may be injected into the first insulating layer INS1 to increase the oxygen concentration of the first insulating layer INS1. For example, oxygen (O) may be uniformly injected into the entire area of the first insulating layer INS1, thereby increasing the overall oxygen concentration of the first insulating layer INS1.

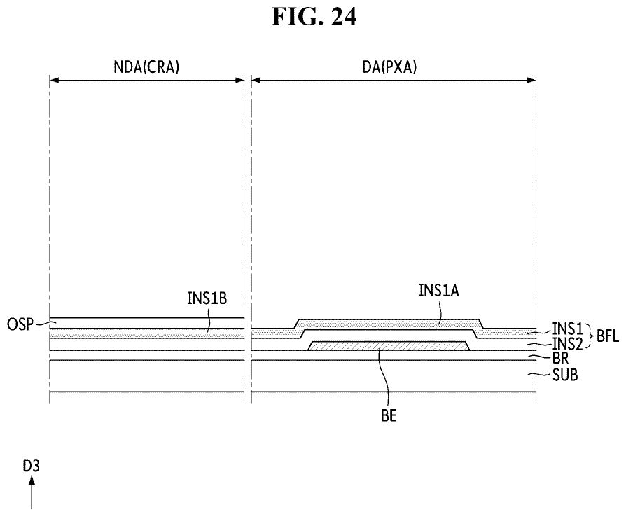

Next, the oxide semiconductor layer OSL may be etched. Accordingly, as illustrated in FIG. 24, an oxide semiconductor pattern OSP may be formed on a portion of the first insulating layer INS1 which is set as the second portion INS1B (e.g., a portion to be formed as the second portion INS1B of the first insulating layer INS1), and another portion of the first insulating layer INS1 which is set as the first portion INS1A of the first insulating layer INS1 (e.g., a portion to be formed as the first portion INS1A of the first insulating layer INS1) may be exposed.

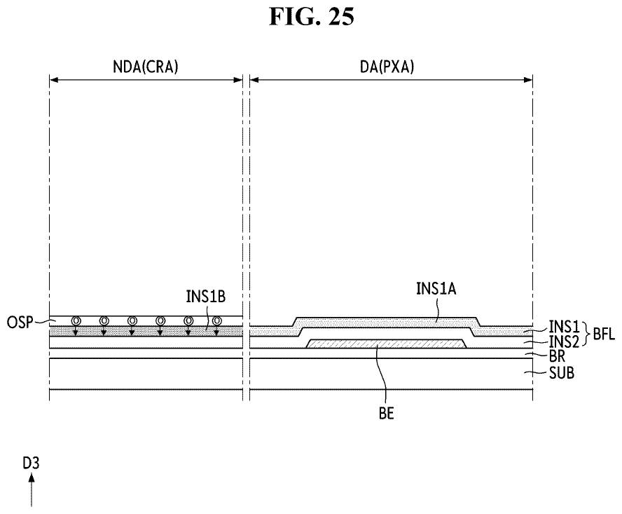

Next, as illustrated in FIG. 25, oxygen (O) may be additionally injected into the second portion INS1B of the first insulating layer INS1 located under the oxide semiconductor pattern OSP by performing heat treatment to apply heat to the oxide semiconductor pattern OSP. Since the oxide semiconductor pattern OSP is not disposed on the first portion INS1A of the first insulating layer INS1, the amount of oxygen injected into the first portion INS1A of the first insulating layer INS1 may be less than the amount of oxygen injected into the second portion INS1B of the first insulating layer INS1. Accordingly, the oxygen concentration of the second portion INS1B of the first insulating layer INS1 may be higher than the oxygen concentration of the first portion INS1A of the first insulating layer INS1.

Next, the oxide semiconductor pattern OSP may be removed as illustrated in FIG. 16, and a first transistor T1 and a second transistor T2 may be formed as illustrated in FIGS. 17 through 21. Then, a planarization layer VIA and a via hole VH may be formed as illustrated in FIG. 22. Through the above-described process, the panel circuit layer PCL of the display panel 110 according to the embodiment may be formed.

As described above, according to a display device 100 and a method of manufacturing the same according to embodiments, a first insulating layer INS1 may include a first portion INS1A and a second portion INS1B having different oxygen concentrations. In embodiments, the oxygen concentration of the second portion INS1B of the first insulating layer INS1 may be higher than the oxygen concentration of the first portion INS1A of the first insulating layer INS1. For example, before the formation of active layers ACT for forming first and second transistors T1 and T2 of the display device 100, a mask pattern MPT and an oxide semiconductor layer OSL may be formed on the first insulating layer INS1 which is to be disposed under the active layers ACT, or an oxide semiconductor pattern OSP may be formed by forming and etching an oxide semiconductor layer OSL. Then, a bottom oxidation process may be performed to increase the oxygen concentration of the second portion INS1B of the first insulating layer INS1 using the mask pattern MPT, the oxide semiconductor layer OSL and/or the oxide semiconductor pattern OSP. For example, the oxygen concentration of the second portion INS1B of the first insulating layer INS1 may be increased by a selective bottom oxidation process of injecting oxygen (O) only into a portion of the first insulating layer INS1 which corresponds to the second portion INS1B or additionally injecting oxygen (O) only into a portion of the first insulating layer INS1.

In embodiments, at least one first transistor T1 may be formed on the first portion INS1A of the first insulating layer INS1, and at least one second transistor T2 may be formed on the second portion INS1B of the first insulating layer INS1. In embodiments, the active layer ACT of each of the first transistor T1 and the second transistor T2 may include an oxide semiconductor.

According to embodiments, it may be possible to simultaneously form the first transistor T1 and the second transistor T2 and may be possible to differentiate and/or optimize the characteristics of the first transistor T1 and the second transistor T2 according to the operating characteristics required of each of the transistors.

For example, since the first transistor T1 is formed on the first portion INS1A of the first insulating layer INS1 having a low oxygen concentration, it is possible to prevent or reduce the injection of excessive oxygen into the active layer ACT of the first transistor T1 during a process of manufacturing the display device 100. Accordingly, it is possible to prevent or reduce a change in a threshold voltage of the first transistor T1 (e.g., a positive shift of the threshold voltage) and improve or secure the operating characteristics and reliability of the first transistor T1.

On the other hand, since the second transistor T2 is formed on the second portion INS1B of the first insulating layer INS1 having a high oxygen concentration, the amount of oxygen flowing into the active layer ACT of the second transistor T2 may be increased during the process of manufacturing the display device 100. Accordingly, it is possible to control or optimize a threshold voltage of the second transistor T2 without increasing a channel length of the second transistor T2. For example, since the amount of oxygen flowing into the active layer ACT of the second transistor T2 increases, in case that the second transistor T2 is formed as a short-channel transistor, it is possible to prevent the threshold voltage of the second transistor T2 from decreasing to the extent that a roll-off phenomenon occurs. For example, the second transistor T2 may have a high threshold voltage compared to its channel length. Accordingly, the operating characteristics and reliability of the second transistor T2 can be improved or secured.

The display device 100 according to an embodiment of the disclosure can be applied to various electronic devices. The electronic device according to the embodiment of the disclosure includes the display device 100 described above, and may further include modules or devices having additional functions in addition to the display device 100.

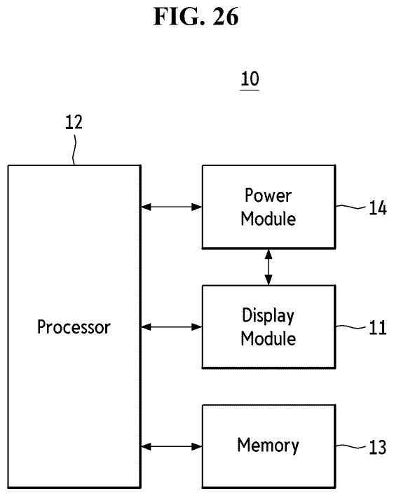

FIG. 26 is a schematic block diagram of an electronic device according to an embodiment of the disclosure.

Referring to FIG. 26, the electronic device 10 according to an embodiment of the disclosure may include a display module 11, a processor 12, a memory 13, and a power module 14.

The display module 11 may include a display panel for displaying an image. For example, the display module 11 may include the display panel 110 according to at least one of the embodiments described above.

The processor 12 may include at least one of a central processing unit (CPU), an application processor (AP), a graphic processing unit (GPU), a communication processor (CP), an image signal processor (ISP), and a controller.

The memory 13 may store data information desirable for the operation of the processor 12 or the display module 11. The processor 12 may transmit an image data signal and/or an input control signal stored in the memory 13 to the display module 11. For example, the processor 12 executes an application stored in the memory 13, an image data signal and/or an input control signal is transmitted to the display module 11, and the display module 11 can process the received signal and output image information through a display screen.

The power module 14 may include a power supply module such as a power adapter or a battery, and a power conversion module that converts the power supplied by the power supply module to generate power desirable for the operation of the electronic device 10.

At least one of the components of the electronic device 10 according to an embodiment of the disclosure may be included in the display device 100 according to the embodiments of the disclosure. Some modules of the individual modules functionally included in a module may be included in the display device 100, and other modules may be provided separately from the display device 100. For example, the display device 100 may include the display module 11, and the processor 12, the memory 13, and the power module 14 may be provided in the form of other devices in the electronic device 10 other than the display device 100.

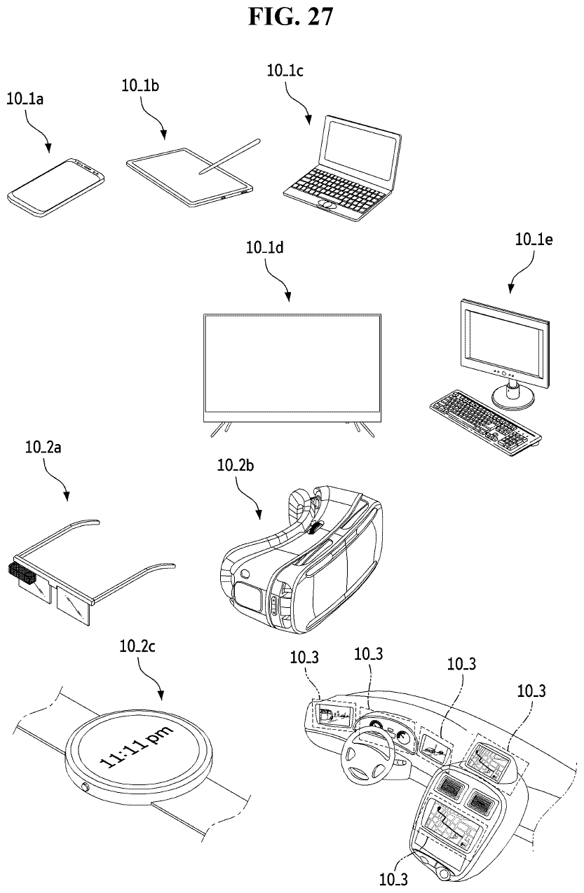

FIG. 27 is a schematic diagram of an electronic device according to various embodiments of the disclosure.

Referring to FIG. 27, various electronic devices 10 to which display devices according to embodiments of the disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display disposed on a dashboard, center fascia, and dashboard of an automobile.

In concluding the detailed description, those skilled in the art will appreciate that many variations and modifications can be made to the embodiments without substantially departing from the principles of the embodiments of the disclosure. Therefore, the disclosed embodiments of the disclosure are used in a generic and descriptive sense only and not for purposes of limitation.

What is claimed is:

1. A display device comprising:
a substrate comprising a display area and a non-display area;
a first insulating layer disposed on the substrate and comprising oxygen;
a first transistor comprising a first active layer disposed on a first portion of the first insulating layer and a first gate electrode overlapping the first active layer; and
a second transistor comprising a second active layer disposed on a second portion of the first insulating layer and a second gate electrode overlapping the second active layer,
wherein an oxygen concentration of the second portion of the first insulating layer is higher than an oxygen concentration of the first portion of the first insulating layer.

2. The display device of claim 1, wherein the first active layer and the second active layer comprise an oxide semiconductor.

3. The display device of claim 1, wherein the first active layer and the second active layer are disposed on a same layer and comprise a same material.

4. The display device of claim 1, wherein
the first portion of the first insulating layer is disposed in at least a portion of the display area, and
the second portion of the first insulating layer is disposed in the non-display area.

5. The display device of claim 4, further comprising:
a pixel disposed in the display area, wherein
the first transistor comprises a driving transistor of the pixel,
the first portion of the first insulating layer is disposed in a portion of a pixel area where the pixel is disposed, and
the second portion of the first insulating layer is disposed in another portion of the pixel area.

6. The display device of claim 5 wherein
the second transistor comprises a switching transistor disposed in the another portion of the pixel area, and
a channel length of the switching transistor is shorter than a channel length of the driving transistor.

7. The display device of claim 4, further comprising:
a driver or a demultiplexer disposed in the non-display area, wherein
the second transistor comprises a circuit transistor included in the driver or the demultiplexer.

8. The display device of claim 1, further comprising a second insulating layer disposed between the substrate and the first insulating layer.

9. The display device of claim 8, wherein
the first insulating layer comprises silicon oxide, and
the second insulating layer comprises silicon nitride.

10. The display device of claim 1, further comprising a gate insulating layer disposed between the first active layer and the first gate electrode and between the second active layer and the second gate electrode.

11. The display device of claim 10, wherein
the gate insulating layer is disposed only on a portion of each of the first active layer and the second active layer and a channel region of each of the first active layer and the second active layer, and
the gate insulating layer exposes another portion of each of the first active layer and the second active layer.

12. The display device of claim 1, further comprising:
a panel circuit layer comprising the first insulating layer, the first transistor, and the second transistor; and
a light emitting element layer disposed on the panel circuit layer and comprising a light emitting element.

13. A method of manufacturing a display device, the method comprising:
forming a first insulating layer on a substrate;
injecting oxygen into a portion of the first insulating layer to differentiate an oxygen concentration of a first portion of the first insulating layer and an oxygen concentration of a second portion of the first insulating layer; and
forming a first transistor and a second transistor on the first portion and the second portion of the first insulating layer, respectively.

14. The method of claim 13, wherein the injecting of the oxygen into the portion of the first insulating layer comprises:
forming a mask pattern on the first portion of the first insulating layer and exposing the second portion of the first insulating layer;
forming an oxide semiconductor layer on the first insulating layer and on the mask pattern; and
removing the mask pattern and the oxide semiconductor layer.

15. The method of claim 13, wherein the injecting of the oxygen into the portion of the first insulating layer comprises:
forming an oxide semiconductor layer on the first insulating layer;
etching the oxide semiconductor layer to form an oxide semiconductor pattern on the second portion of the first insulating layer and expose the first portion of the first insulating layer;
performing heat treatment by applying heat to the oxide semiconductor pattern; and
removing the oxide semiconductor pattern.

16. The method of claim 13, wherein the forming of the first transistor and the second transistor comprises:
forming an active layer of the first transistor and an active layer of the second transistor on the first portion and the second portion of the first insulating layer, respectively; and
forming a gate insulating layer, a gate electrode of the first transistor, and a gate electrode of the second transistor on the active layer of the first transistor and the active layer of the second transistor.

17. The method of claim 16, wherein the active layer of the first transistor and the active layer of the second transistor comprise an oxide semiconductor.

18. The method of claim 13, further comprising:
forming a second insulating layer on the substrate before the forming of the first insulating layer, wherein
the first insulating layer comprises silicon oxide, and
the second insulating layer comprises silicon nitride.

19. An electronic device comprising:
a display module including a display panel; and
a processor that transmits an image data signal to the display module,
wherein the display panel comprises:
a substrate comprising a display area and a non-display area;
a first insulating layer disposed on the substrate and comprising oxygen;
a first transistor comprising a first active layer disposed on a first portion of the first insulating layer and a first gate electrode overlapping the first active layer; and
a second transistor comprising a second active layer disposed on a second portion of the first insulating layer and a second gate electrode overlapping the second active layer, and
wherein an oxygen concentration of the second portion of the first insulating layer is higher than an oxygen concentration of the first portion of the first insulating layer.

20. The electronic device of claim 19, wherein the first active layer and the second active layer comprise an oxide semiconductor.
